(19) United States
(12) Patent Application Publication
(10) Pub. No.: US 2018/0033854 A1
(43) Pub. Date: Feb. 1, 2018

(54) SEMICONDUCTOR DEVICE AND MANUFACTURING METHOD THEREOF

(71) Applicant: Renesas Electronics Corporation, Tokyo (JP)

(72) Inventors: Yoshinori KAYA, Ibaraki (JP); Yasushi NAKAHARA, Ibaraki (JP)

(73) Assignee: Renesas Electronics Corporation, Tokyo (JP)

(21) Appl. No.: 15/631,144

(22) Filed: Jun. 23, 2017

(30) Foreign Application Priority Data
Jul. 28, 2016 (JP) 2016-148609

(51) Int. Cl. H01L 29/06; H01L 27/092; H01L 21/8238; H01L 29/40

(52) U.S. Cl. CPC H01L 29/063; H01L 29/402; H01L 27/092; H01L 21/823807

(57) ABSTRACT

An object of the present invention is to improve the performance of a semiconductor device.

A p-channel transistor formed in a separation region has a RESURF layer that functions as a current path, is formed in an epitaxial layer, and is a p-type semiconductor layer, and a buried layer that is overlapped with the RESURF layer in planar view, is formed under the RESURF layer, is sandwiched between a semiconductor substrate and the epitaxial layer, and is an p-type semiconductor layer.

### CROSS-REFERENCE TO RELATED APPLICATIONS

The disclosure of Japanese Patent Application No. 2016-148609 filed on Jul. 28, 2016 including the specification, drawings and abstract is incorporated herein by reference in its entirety.

### BACKGROUND

The present invention relates to a semiconductor device and a manufacturing technique thereof, and relates to an effective technique applied to a semiconductor device having, for example, a low voltage circuit operated at a first potential with respect to a reference potential and a high voltage circuit operated at a potential equal to or higher than the first potential with respect to the reference potential and a manufacturing method thereof.

Japanese Unexamined Patent Application Publication No. 2005-123512 describes a technique of providing a level shift transistor in a separation region that separates a high potential reference circuit from a low potential reference circuit in a semiconductor device in which the low potential reference circuit and the high potential reference circuit are mixed.

### SUMMARY

For example, there exists a semiconductor chip in which a low voltage circuit operated at a first potential with respect to a reference potential and a high voltage circuit operated at a potential equal to or higher than the first potential with respect to the reference potential are formed and which includes a separation region that separates the high voltage circuit from the low voltage circuit. A semiconductor device with such a semiconductor chip mounted can function as, for example, a control circuit (pre-driver) for controlling a power circuit. Namely, the above-described semiconductor device can be used for controlling a high-side power transistor configuring an upper arm of the power circuit and a low-side power transistor configuring a lower arm of the power circuit.

Specifically, switching (on/off) of the high-side power transistor can be controlled by the high voltage circuit, and switching (on/off) of the low-side power transistor can be controlled by the low voltage circuit.

Here, the operating voltage of the high voltage circuit largely differs from that of the low voltage circuit, and thus the high voltage circuit is separated from the low voltage circuit by the separation region. However, in order to transmit signals such as an overcurrent detection signal and a temperature detection signal of the high-side power transistor from the high voltage circuit to the low voltage circuit, a level shift transistor having a function of signal transmission from the high voltage circuit to the low voltage circuit is desirably formed in the separation region in some cases.

As a result of examination from the viewpoint of improving the performance of the level shift transistor, the inventors newly found that there was room for improvement to decrease on-resistance while maintaining a breakdown voltage.

The other objects and novel features will become apparent from the description of the specification and the accompanying drawings.

A semiconductor device in an embodiment has a RESURF layer that functions as a current path, is formed in an epitaxial layer, and is of a second conductive type opposite to a first conductive type, and a buried layer that is overlapped with the RESURF layer in planar view, is formed under the RESURF layer, is sandwiched between a semiconductor substrate and the epitaxial layer, and is of the first conductive type.

According to an embodiment, the performance of a semiconductor device can be improved.

### BRIEF DESCRIPTION OF THE DRAWINGS

FIG. 1 is a diagram for showing a schematic planar configuration of a semiconductor chip in an embodiment;

FIG. 2 is a diagram for showing a circuit block configuration of the semiconductor chip in the embodiment;

FIG. 3 is a schematic view for explaining a configuration example of a level up shifter included in a level shift circuit;

FIG. 4 is a schematic view for explaining a configuration example of a level down shifter included in the level shift circuit;

FIG. 5 is a diagram for showing a planar layout configuration of the semiconductor chip in which a p-channel transistor formation region is provided at a part of a separation region and a p-channel transistor functioning as the level down shifter is formed in the p-channel transistor formation region;

FIG. 6 is a cross-sectional view for schematically showing a device structure of the p-channel transistor formed in the p-channel transistor formation region;

FIG. 7 is a diagram for showing a planar configuration of the semiconductor chip in which not only the p-channel transistor formation region but also an n-channel transistor formation region is provided in the separation region;

FIG. 8 is a cross-sectional view for schematically showing a device structure of an n-channel transistor formed in the n-channel transistor formation region;

FIG. 9 is a diagram for showing a planar layout configuration of the semiconductor chip in the embodiment;

FIG. 10 is a diagram for showing a schematic planar layout configuration of the n-channel transistor, the p-channel transistor, and a rectifying element formed in the separation region in the semiconductor chip;

FIG. 11 is a cross-sectional view taken along the line A-A of FIG. 10;

FIG. 12 is a cross-sectional view taken along the line B-B of FIG. 10;

FIG. 13 is a cross-sectional view taken along the line C-C of FIG. 10;

FIG. 14 is a diagram for explaining an effect in the embodiment;

FIG. 15 is a cross-sectional view for showing a device structure of a p-channel transistor in a modified example 1;

FIG. 16 is a cross-sectional view for showing a device structure of a p-channel transistor in a modified example 2;

FIG. 17A is a cross-sectional view for showing a manufacturing process of the semiconductor device in the embodiment, and FIG. 17B is a cross-sectional view for showing a manufacturing process of the semiconductor device subsequent to FIG. 17A;

FIG. 18A is a cross-sectional view for showing a manufacturing process of the semiconductor device in the embodiment, and FIG. 18B is a cross-sectional view for showing a manufacturing process of the semiconductor device subsequent to FIG. 18A;

FIG. 19A is a cross-sectional view for showing a manufacturing process of the semiconductor device in the embodiment, and FIG. 19B is a cross-sectional view for showing a manufacturing process of the semiconductor device subsequent to FIG. 19A;

FIG. 20A is a cross-sectional view for showing a manufacturing process of the semiconductor device in the embodiment, and FIG. 20B is a cross-sectional view for showing a manufacturing process of the semiconductor device subsequent to FIG. 20A;

FIG. 21A is a cross-sectional view for showing a manufacturing process of the semiconductor device in the embodiment, and FIG. 21B is a cross-sectional view for showing a manufacturing process of the semiconductor device subsequent to FIG. 21A;

FIG. 22A is a cross-sectional view for showing a manufacturing process of the semiconductor device in the embodiment, and FIG. 22B is a cross-sectional view for showing a manufacturing process of the semiconductor device subsequent to FIG. 22A;

FIG. 23A is a cross-sectional view for showing a manufacturing process of the semiconductor device in the embodiment, and FIG. 23B is a cross-sectional view for showing a manufacturing process of the semiconductor device subsequent to FIG. 23A;

FIG. 24A is a cross-sectional view for showing a manufacturing process of the semiconductor device in the embodiment, and FIG. 24B is a cross-sectional view for showing a manufacturing process of the semiconductor device subsequent to FIG. 24A; and

FIG. 25 is a cross-sectional view for showing a manufacturing process of the semiconductor device subsequent to FIG. 24B.

### DETAILED DESCRIPTION

The present invention will be described using the following embodiment while being divided into a plurality of sections or embodiments if necessary for convenience sake. However, except for a case especially specified, the sections or embodiments are not irrelevant to each other, and one has a relationship as a part of a modified example or a complete modified example, or a detailed or supplementary explanation of the other.

Further, if the specification refers to the number of elements (including the number of pieces, values, amounts, ranges, and the like) in the following embodiment, the present invention is not limited to the specific number, but may be smaller or larger than the specific number, except for a case especially specified or a case obviously limited to the specific number in principle.

Furthermore, it is obvious that the constitutional elements (including elemental steps and the like) are not necessarily essential in the following embodiment except for a case especially specified or a case obviously deemed to be essential in principle.

Likewise, if the specification refers to the shapes or positional relationships of the constitutional elements in the following embodiment, the present invention includes those that are substantially close or similar to the constitutional elements in shapes and the like, except for a case especially specified or a case obviously deemed not to be close or similar in principle. The same applies to the values and ranges.

Further, the same members will be followed by the same signs in principle in all the drawings for explaining the embodiment, and the explanations thereof will not be repeated. It should be noted that hatchings will be given in some cases even in the case of plan views in order to easily understand the drawings.

### <Schematic Planar Configuration of Semiconductor Chip>

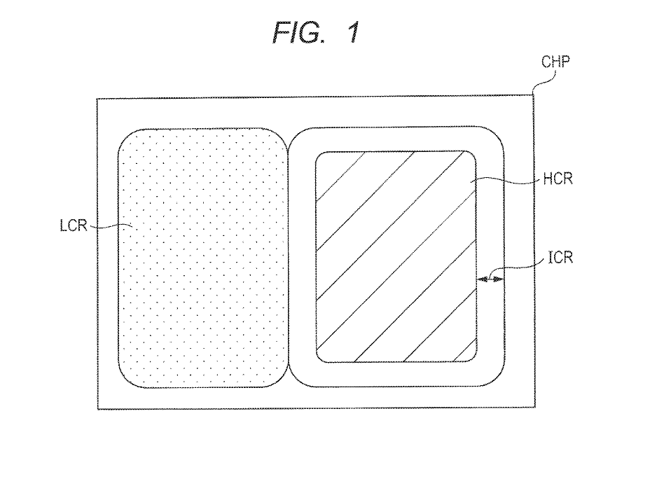

FIG. 1 is a diagram for showing a schematic planar configuration of a semiconductor chip CHP in an embodiment. In FIG. 1, the semiconductor chip CHP in the embodiment has a rectangular planar shape. In addition, as shown in FIG. 1, a low voltage circuit region LCR, a high voltage circuit region HCR, a separation region ICR that separates the high voltage circuit region HCR from the low voltage circuit region LCR are formed in the semiconductor chip CHP. Namely, the semiconductor chip CHP in the embodiment has the low voltage circuit region LCR in which a low voltage circuit operated at a first potential with respect to a reference potential (GND potential) is formed, the high voltage circuit region HCR in which a high voltage circuit operated at a potential equal to or higher than the first potential with respect to the reference potential is formed, and the separation region ICR that separates the high voltage circuit region HCR from the low voltage circuit region LCR.

A semiconductor device including the semiconductor chip CHP thus configured is used as, for example, a constitutional element of an inverter. Specifically, the semiconductor device including the semiconductor chip CHP can be used as a control circuit (pre-driver) that controls a power circuit of an inverter driving a load such as a motor. Because the power circuit has a high-side power transistor configuring an upper arm, and a low-side power transistor configuring a lower arm. Namely, a switching operation of the low-side power transistor can be controlled by the low voltage circuit operated at the first potential with respect to the reference potential. On the other hand, a switching operation of the high-side power transistor needs to be controlled by the high voltage circuit operated at a potential higher than the first potential with respect to the reference potential.

In the case where the low voltage circuit and the high voltage circuit are formed in one semiconductor chip as described above, the operating voltage of the low voltage circuit largely differs from that of the high voltage circuit, and thus it is necessary to provide the separation region ICR to separate the high voltage circuit region HCR in which the high voltage circuit is formed from the low voltage circuit region LCR in which the low voltage circuit is formed.

As described above, the semiconductor chip in the embodiment has the low voltage circuit region LCR, the high voltage circuit region HCR, and the separation region ICR that separates the high voltage circuit region HCR from the low voltage circuit region LCR.

### <Circuit Block Configuration of Semiconductor Chip>

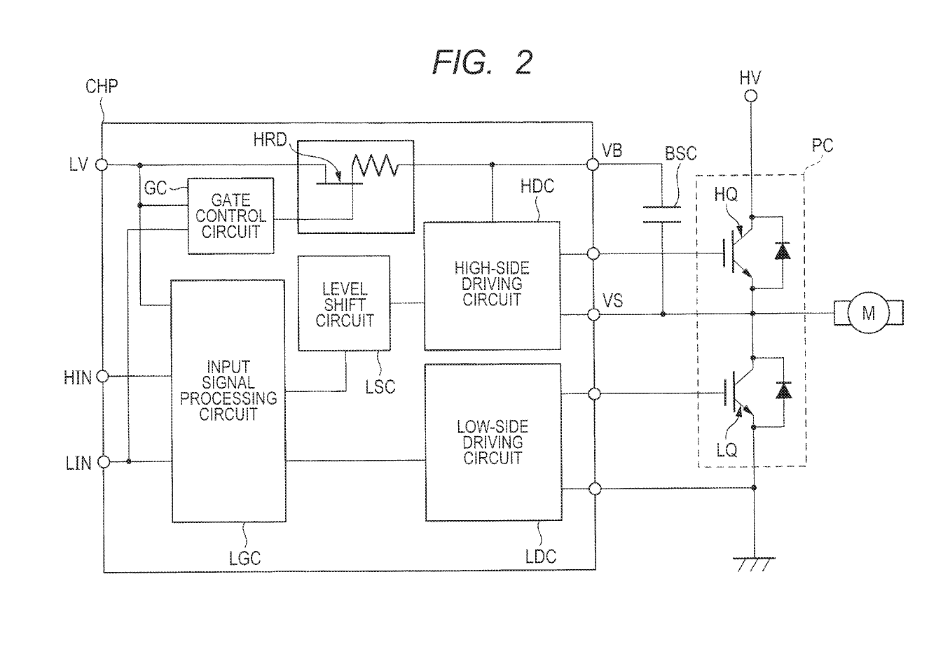

Next, a circuit block configuration of the semiconductor chip CHP in the embodiment will be described. FIG. 2 is a diagram for showing a circuit block configuration of the semiconductor chip CHP in the embodiment. FIG. 2 shows a configuration example in which a control circuit formed in the semiconductor chip CHP of the embodiment is used to control a switching operation of a power circuit PC controlling electric power input to the motor M that is a load.

First, the power circuit PC has a high-side power transistor HQ and a low-side power transistor LQ that are coupled to each other in series between a terminal HV to which a high potential is supplied and a ground potential (reference potential). In this case, the motor M is coupled to a connection node between the high-side power transistor HQ and the low-side power transistor LQ.

Here, the “power transistor” in the specification means an assembly of cell transistors for realizing the function of the cell transistor even with a current larger than an allowable current of the cell transistor by coupling the cell transistors in parallel (for example, several thousands to hundreds of thousands of cell transistors are coupled in parallel). For example, in the case where the cell transistor functions as a switching element, the “power transistor” serves as a switching element that can be applied to a current larger than an allowable current of the cell transistor. In particular, the term of the “power transistor” in the specification is used as words representing a superordinate concept including, for example, both of a “power MOSFET” and an “IGBT”.

Next, the control circuit controlling a switching operation of each of the high-side power transistor HQ and the low-side power transistor LQ configuring the power circuit PC is formed in the semiconductor chip CHP in the embodiment.

Specifically, the semiconductor chip CHP in the embodiment includes an input signal processing circuit LGC, a gate control circuit GC, a level shift circuit LSC, a high-side driving circuit HDC, a low-side driving circuit LDC, and a rectifying element HRD.

The input signal processing circuit LGC is configured using a logic circuit, and is configured to generate a control signal for controlling the motor M on the basis of signals input from, for example, a terminal HIN and a terminal LIN. The control signal includes a signal for controlling the low-side driving circuit LDC and a signal for controlling the high-side driving circuit HDC. It should be noted that the input signal processing circuit LGC is also electrically coupled to a terminal LV to which a low potential is supplied.

Next, the low-side driving circuit LDC is electrically coupled to the input signal processing circuit LGC, and is configured to control switching (on/off) of the low-side power transistor LQ configuring a part of the power circuit PC on the basis of a signal input from the input signal processing circuit LGC. Specifically, the low-side driving circuit LDC is configured to generate a voltage signal equal to or higher than a threshold voltage with respect to the reference potential (GND potential), and is configured to turn on the low-side power transistor LQ by applying the voltage signal to the gate electrode of the low-side power transistor LQ of the power circuit PC. On the other hand, the low-side driving circuit LDC is also configured to generate a voltage signal equal to or lower than the threshold voltage, and is configured to turn off the low-side power transistor LQ by applying the voltage signal to the gate electrode of the low-side power transistor LQ of the power circuit PC. It should be noted that the operating voltage of the input signal processing circuit LGC is nearly the same as that of the low-side driving circuit LDC, and thus the input signal processing circuit LGC and the low-side driving circuit LDC are directly and electrically coupled to each other.

Next, the high-side driving circuit HDC is electrically coupled to the input signal processing circuit LGC through the level shift circuit LSC, and is configured to control switching (on/off) of the high-side power transistor HQ configuring a part of the power circuit PC on the basis of a signal input from the input signal processing circuit LGC. Specifically, the high-side driving circuit HDC is configured to generate a voltage signal equal to or higher than a threshold voltage of the high-side power transistor HQ with respect to the reference potential (GND potential), and is configured to turn on the high-side power transistor HQ by applying the voltage signal to the gate electrode of the high-side power transistor HQ of the power circuit PC. On the other hand, the high-side driving circuit HDC is also configured to generate a voltage signal lower than the threshold voltage, and is configured to turn off the high-side power transistor HQ by applying the voltage signal to the gate electrode of the high-side power transistor HQ of the power circuit PC.

Here, necessity of generating the voltage signal equal to or higher than the threshold voltage serving as a second potential that is higher than a first potential with respect to the reference potential (GND potential) in the high-side driving circuit HDC will be described. As shown in FIG. 2, the high-side driving circuit HDC is electrically coupled to a terminal VS, and the terminal VS is electrically coupled to the connection node between the high-side power transistor HQ and the low-side power transistor LQ of the power circuit PC. In this case, for example, a signal to turn on the low-side power transistor LQ of the power circuit PC in FIG. 2 is a voltage signal having the first potential with respect to the reference potential (GND potential). On the contrary, a signal to turn on the high-side power transistor HQ of the power circuit PC is not, for example, a voltage signal having the first potential with respect to the reference potential (GND potential). Because the signal to turn on the high-side power transistor HQ of the power circuit PC needs to be not a signal having the first potential with respect to the reference potential (GND potential) but a signal having the first potential with respect to a potential supplied to the terminal VS as shown in FIG. 2. Namely, the potential supplied to the terminal VS becomes the same potential as the reference potential (GND potential) when the low-side power transistor LQ is turned on. On the other hand, the potential supplied to the terminal VS becomes nearly the same potential as a high potential applied to the terminal HV when the high-side power transistor HQ is turned on. Thus, a signal necessary to turn on the high-side power transistor HQ needs to be a voltage signal having the first potential with respect to the high potential. In other words, a signal necessary to turn on the high-side power transistor HQ needs to be a voltage signal having the second potential higher than the first potential with respect to the reference potential (GND potential).

As described above, the operating voltage of the high-side driving circuit HDC becomes higher than that of the low-side driving circuit LDC. Thus, the operating voltage of the input signal processing circuit LGC largely differs from that of the high-side driving circuit HDC. As a result, the input signal processing circuit LGC and the high-side driving circuit HDC are electrically coupled to each other through the level shift circuit LSC.

Next, the level shift circuit LSC is a circuit provided to enable signal transmission between the input signal processing circuit LGC and the high-side driving circuit HDC that are different from each other in the operating voltage. For example, a level up shifter is necessary to enable signal transmission from the input signal processing circuit LGC to the high-side driving circuit HDC. On the other hand, a level down shifter is necessary to enable signal transmission from the high-side driving circuit HDC to the input signal processing circuit LGC. Thus, the level shift circuit LSC is configured using, for example, the level up shifter and the level down shifter.

Next, as shown in FIG. 2, the terminal LV to which a low potential is supplied and a terminal VB are electrically coupled to each other through the rectifying element HRD including a gate electrode, and an external bootstrap capacitor BSC is electrically coupled between the terminal VB and the terminal VS. In addition, the gate electrode of the rectifying element HRD is coupled to the gate control circuit GC.

The gate control circuit GC is electrically coupled to the terminal LIN and the terminal LV, and is configured to realize the rectifying function of the rectifying element HRD by controlling a signal applied to the gate electrode of the rectifying element HRD.

The circuit block configuration of the semiconductor chip CHP in the embodiment is realized as described above. In a correspondence relation between FIG. 1 and FIG. 2 of this case, the input signal processing circuit LGC, the low-side driving circuit LDC, and the gate control circuit GC shown in FIG. 2 are formed in the low voltage circuit region LCR shown in FIG. 1, and the high-side driving circuit HDC shown in FIG. 2 is formed in the high voltage circuit region HCR shown in FIG. 1. On the other hand, the level shift circuit LSC and the rectifying element HRD are formed in the separation region ICR.

### <Circuit Operation of Semiconductor Chip>

Next, a control operation of the power circuit PC by the control circuit formed in the semiconductor chip CHP in the embodiment will be described with reference to FIG. 2.

First, in the case where electric charges are not accumulated in the external bootstrap capacitor BSC, an “L level” signal is input to the terminal HIN, and an “H level” signal is input to the terminal LIN. Here, in the case where the “L level” signal is input to the terminal HIN, the high-side power transistor HQ of the power circuit PC is turned off under the control through the input signal processing circuit LG, the level shift circuit LSC, and the high-side driving circuit HDC. On the other hand, in the case where the “H level” signal is input to the terminal LIN, the low-side power transistor LQ of the power circuit PC is turned on under the control through the input signal processing circuit LGC and the low-side driving circuit LDC. In this case, the potential of the terminal VS becomes nearly the same potential as the reference potential (GND potential), and becomes lower than the low potential input from the terminal LV. As a result, when the rectifying element HRD is turned on under the control of the gate control circuit GC, a current flows from the terminal LV to which the low potential is supplied towards the terminal VS. Thus, electric charges are accumulated (charged) in the bootstrap capacitor BSC.

Next, in the case where electric charges are accumulated in the external bootstrap capacitor BSC, an “H level” signal is input to the terminal HIN, and an “L level” signal is input to the terminal LIN. In this case, the high-side power transistor HQ of the power circuit PC is turned on by the discharge current of the bootstrap capacitor BSC. On the other hand, the low-side power transistor LQ of the power circuit PC is turned off. Accordingly, the potential of the terminal VS becomes nearly the same potential as the high potential supplied to the terminal HV.

As described above, the potential of the terminal VS fluctuates between the reference potential (GND potential) and the high potential by alternately repeating the on/off operation of the high-side power transistor HQ of the power circuit PC and the on/off operation of the low-side power transistor LQ of the power circuit PC. In addition, this means that output electric power supplied to the motor M electrically coupled to the terminal VS fluctuates, and thereby the motor M can be controlled. As described above, according to the control circuit formed in the semiconductor chip CHP in the embodiment, it can be understood that the motor M that is a load can be controlled by controlling the switching of the power circuit PC.

### <Configuration of Level Up Shifter>

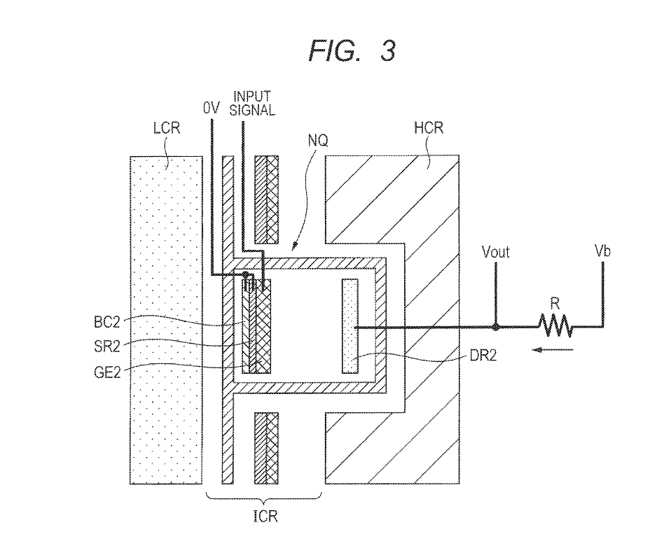

Next, FIG. 3 is a schematic view for explaining a configuration example of the level up shifter included in the level shift circuit LSC. In FIG. 3, the separation region ICR is formed at a position sandwiched between the low voltage circuit region LCR and the high voltage circuit region HCR, and an n-channel transistor NQ functioning as the level up shifter is formed in the separation region ICR.

The n-channel transistor NQ has a gate electrode GE2, a source region SR2, and a body contact region BC2 that are arranged adjacent to each other, and has a drain region DR2 arranged apart from the gate electrode GE2.

Here, the source region SR2 and the body contact region BC2 of the n-channel transistor NQ are coupled to the ground, and the reference potential (GND potential, 0V) is applied. On the other hand, the drain region DR2 of the n-channel transistor NQ is configured in such a manner that a potential Vb is supplied through a resistor element R. The potential Vb is the same potential as that applied to the terminal VB shown in FIG. 2.

In addition, when a signal is transmitted from the low voltage circuit region LCR to the high voltage circuit region HCR, an input signal is input from the input signal processing circuit LGC shown in FIG. 2 to the gate electrode GE2 of the n-channel transistor NQ. As a result, the n-channel transistor NQ is turned on, and a current flows from the drain region DR2 to the source region SR2. Accordingly, a voltage pulled down from the potential Vb by a voltage calculated on the basis of “current×resistance value of resistor element R” is output as an output voltage Vout. Namely, the input signal input from the low voltage circuit formed in the low voltage circuit region LCR is converted into the output voltage Vout through level up conversion by the n-channel transistor NQ to be transmitted to the high voltage circuit region HCR as the output voltage Vout. As described above, the level up shifter is realized by the n-channel transistor NQ formed in the separation region ICR.

### <Configuration of Level Down Shifter>

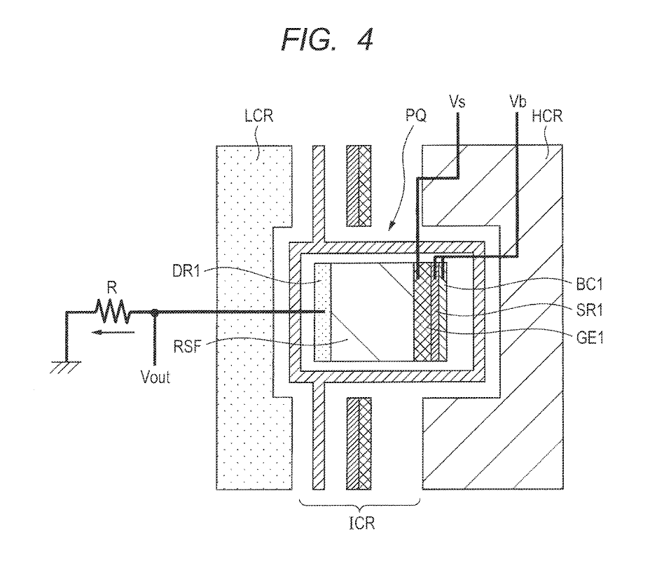

Next, FIG. 4 is a schematic view for explaining a configuration example of the level down shifter included in the level shift circuit LSC. In FIG. 4, the separation region ICR is formed at a position sandwiched between the low voltage circuit region LCR and the high voltage circuit region HCR, and a p-channel transistor PQ functioning as the level down shifter is formed in the separation region ICR.

The p-channel transistor PQ has a gate electrode GE1, a source region SR1, and a body contact region BC1 that are arranged adjacent to each other, and has a drain region DR1 arranged apart from the gate electrode GE1. Further, the p-channel transistor PQ has a RESURF layer RSF sandwiched between the gate electrode GE1 and the drain region DR1. The RESURF layer RSF functions as a current path in which holes flow.

Here, a potential Vb is supplied to the source region SR1 and the body contact region BC1 of the p-channel transistor PQ. On the other hand, the drain region DR1 of the p-channel transistor PQ is electrically coupled to the ground through a resistor element R.

In addition, when a signal is transmitted from the high voltage circuit region HCR to the low voltage circuit region LCR, a potential Vs smaller than the potential Vb is applied to the gate electrode GE1 of the p-channel transistor PQ. The potential Vs is the same potential as that applied to the terminal VS shown in FIG. 2. As a result, the p-channel transistor PQ is turned on, and a current flows from the source region SR1 to the drain region DR1. Accordingly, a voltage pulled up from the reference potential (GND potential) by a voltage calculated on the basis of “current×resistance value of resistor element R” is output as an output voltage Vout. Namely, the input signal input to the gate electrode GE1 of the p-channel transistor PQ from the high voltage circuit formed in the high voltage circuit region HCR is converted into the output voltage Vout through level down conversion by the p-channel transistor PQ to be transmitted to the low voltage circuit region LCR as the output voltage Vout. As described above, the level down shifter is realized by the P-channel transistor PQ formed in the separation region ICR.

### <Examination 1 of Improvement>

For example, the inventions have examined to form the level down shifter (p-channel transistor) having a function of signal transmission from the high voltage circuit formed in the high voltage circuit region HCR to the low voltage circuit formed in the low voltage circuit region LCR in the separation region ICR of the semiconductor chip CHP shown in FIG. 1.

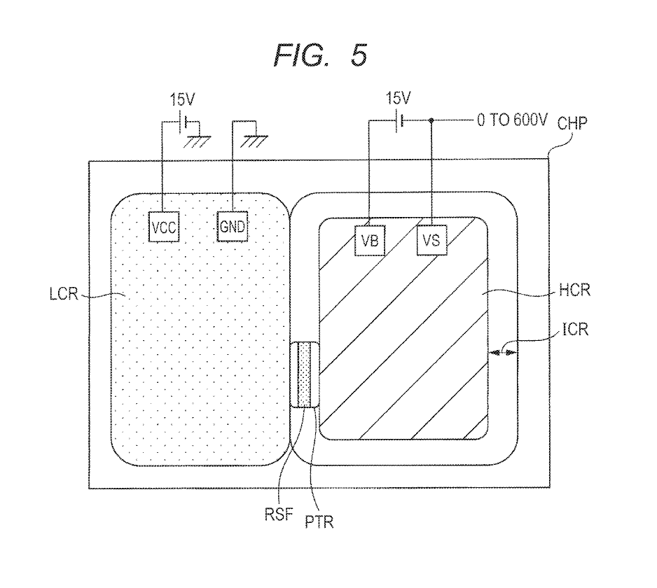

FIG. 5 is a diagram for showing a planar layout configuration of the semiconductor chip CHP in which a p-channel transistor formation region PTR is provided at a part of the separation region ICR and the p-channel transistor functioning as the level down shifter is formed in the p-channel transistor formation region PTR. In FIG. 5, the reference potential (GND) and the power source potential (VCC, 15V) are supplied to the low voltage circuit region LCR. On the other hand, a potential of 0 to 600V is supplied to the terminal VS of the high voltage circuit region HCR, and a potential (15V) higher than that of the terminal VS is supplied to the terminal VB. Accordingly, the low voltage circuit formed in the low voltage circuit region LCR can be operated, and the high voltage circuit formed in the high voltage circuit region HCR can be operated.

For example, an epitaxial layer that is an n-type semiconductor layer is formed across the low voltage circuit region LCR, the separation region ICR, and the high voltage circuit region HCR in the semiconductor chip CHP. In the case where the p-channel transistor is formed in the separation region ICR of the semiconductor chip CHP, the epitaxial layer that is an n-type semiconductor layer does not serve as a current path of the p-channel transistor. Therefore, it is conceivable that a RESURF layer configured using a p-type semiconductor layer is formed on the surface of the epitaxial layer, so that the RESURF layer is used as a current path of the p-channel transistor. Namely, it is conceivable that the RESURF layer RSF is formed in the p-channel transistor formation region PTR of the separation region ICR as shown in FIG. 5.

In the case of the configuration, however, the examination of the inventors clarified room for improvement shown below, and thus this point will be described.

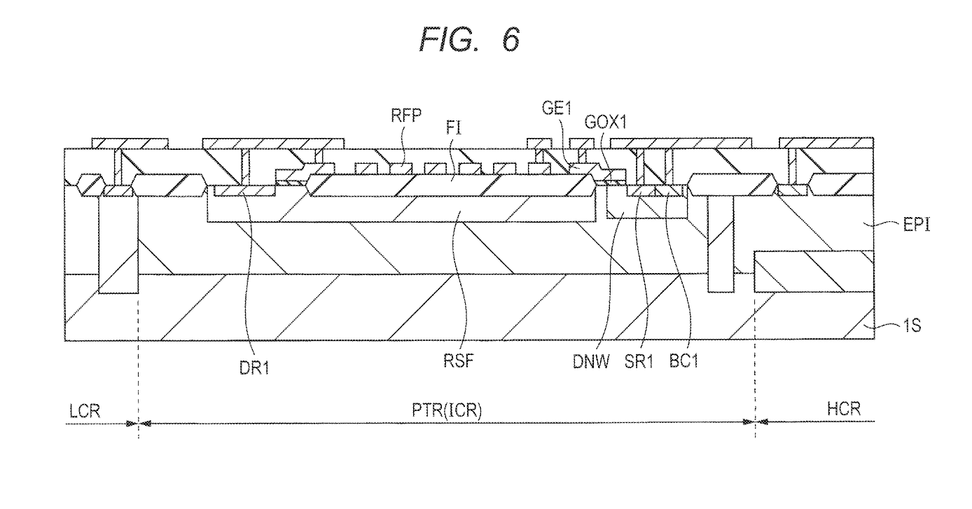

FIG. 6 is a cross-sectional view for schematically showing a device structure of the p-channel transistor formed in the p-channel transistor formation region PTR. In FIG. 6, a device structure in the p-channel transistor formation region PTR existing in the separation region ICR sandwiched between the low voltage circuit region LCR and the high voltage circuit region HCR will be described.

As shown in FIG. 6, an epitaxial layer EPI that is an n-type semiconductor layer is formed on a semiconductor substrate 1S into which, for example, p-type impurities such as boron are introduced. In addition, the RESURF layer RSF that is a p-type semiconductor layer is formed on the surface of the epitaxial layer EPI. A field insulating film FI is formed on the surface of the RESURF layer RSF, and a field plate RFP is formed on the field insulating film FI. Further, a drain region DR1 that is a p-type semiconductor region is formed on the surface of the RESURF layer RSF while being apart from the field insulating film FI. On the other hand, an n-type well DNW is formed at a position adjacent to the RESURF layer RSF on the surface of the epitaxial layer EPI, and a source region SR1 configured using a p-type semiconductor region and a body contact region BC1 configured using an n-type semiconductor region are formed so as to be included in the n-type well DNW. In addition, a region sandwiched between the source region SR1 and the RESURF layer RSF serves as a channel formation region, and a gate insulating film GOX1 is formed on the channel formation region. Further, a gate electrode GE1 is formed on the gate insulating film GOX1.

In the p-channel transistor thus configured, since the RESURF layer RSF is formed on the surface of the epitaxial layer EPI, a p-n junction is formed at a boundary region between the epitaxial layer EPI and the RESURF layer RSF, and a depletion layer extends from the p-n junction in the thickness direction of the semiconductor substrate 1S. In this case, if a breakdown voltage is determined on the basis of the boundary value condition of the Poisson equation in a state where the semiconductor substrate 1S, the epitaxial layer EPI, and the ESURF layer RSF are completely depleted by the depletion layer extending when the p-channel transistor is turned off, the concentration of space charges (donor concentration) of the epitaxial layer EPI is automatically determined. The impurity concentration of the epitaxial layer EPI becomes higher than that of the epitaxial layer EPI in the case where the RESURF layer RSF is not formed. This means that the impurity concentration of the epitaxial layer EPI needs to be increased in the case where the RESURF layer RSF is formed in the p-channel transistor formation region PTR of the separation region ICR. In addition, changes in the impurity concentration of the epitaxial layer EPI mean that device characteristics of the devices formed in the low voltage circuit region LCR and the high voltage circuit region HCR are affected because the epitaxial layer EPI is formed across the low voltage circuit region LCR, the separation region ICR, and the high voltage circuit region HCR. As a result, the formation of the RESURF layer RSF in the p-channel transistor formation region PTR of the separation region ICR means that the design of the devices formed in the low voltage circuit region LCR and the high voltage circuit region HCR needs to be changed. This means that the design of the semiconductor chip CHP is largely changed.

Further, an increase in the impurity concentration of the epitaxial layer EPI means that the depletion layer extending on the RESURF layer RSF side from the p-n junction between the RESURF layer RSF and the epitaxial layer EPI is enlarged. In addition, since the depletion layer itself functions as an insulating layer, the resistance in the RESURF layer RSF functioning as a current path of the p-channel transistor is increased. As a result, the on-resistance of the p-channel transistor is increased.

As described above, in the case where the level down shifter is formed in the separation region ICR, the design of the entire semiconductor chip CHP needs to be changed or the performance of the p-channel transistor itself is deteriorated if only the p-channel transistor having the RESURF layer RSF is formed in the p-channel transistor formation region PTR of the separation region ICR. Thus, it can be understood that there is room for improvement in this regard.

### <Examination 2 of Improvement>

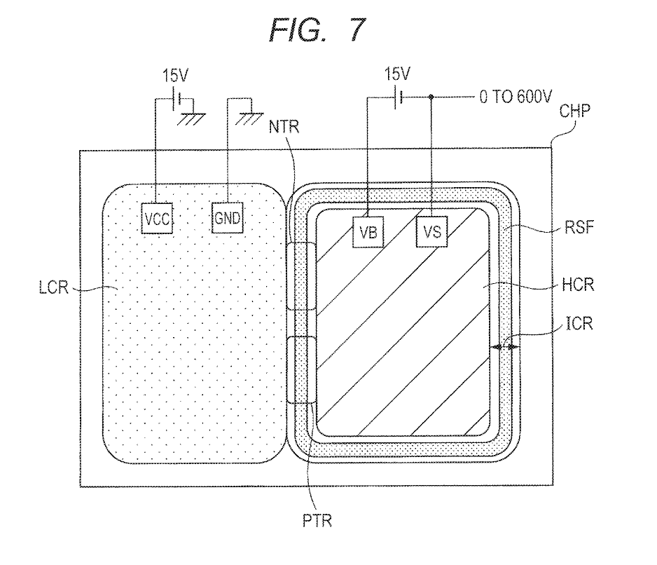

Further, FIG. 7 is a diagram for showing a planar configuration of the semiconductor chip CHP in which not only the p-channel transistor formation region PTR but also an n-channel transistor formation region NTR is provided in the separation region ICR. Namely, as shown in FIG. 7, in the case where the n-channel transistor is formed in the n-channel transistor formation region NTR, it is conceivable that the RESURF layer RSF is formed across the entire separation region ICR. Because in the case where the p-channel transistor having the RESURF layer RSF is formed in the p-channel transistor formation region PTR, the impurity concentration of the epitaxial layer needs to be increased in order to secure the breakdown voltage of the p-channel transistor. In this case, however, it is difficult to secure the breakdown voltage of the n-channel transistor formed in the n-channel transistor formation region NTR. Thus, even if the impurity concentration of the epitaxial layer is increased, it is necessary to secure the breakdown voltage by changing the depletion layer extending from the n-channel transistor by forming the RESURF layer RSF even in the n-channel transistor formation region NTR (double-RESURF structure).

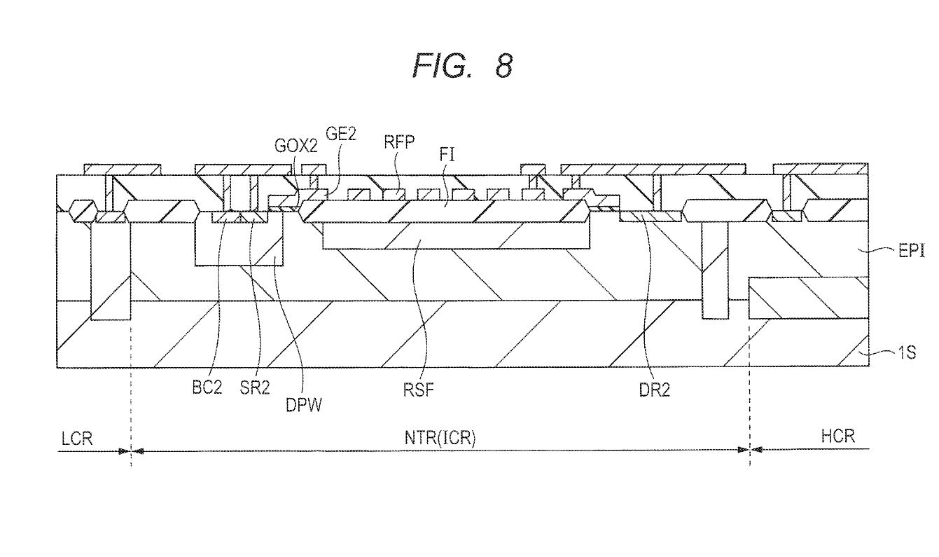

FIG. 8 is a cross-sectional view for schematically showing a device structure of the n-channel transistor formed in the n-channel transistor formation region NTR. In FIG. 8, a device structure in the n-channel transistor formation region NTR existing in the separation region ICR sandwiched between the low voltage circuit region LCR and the high voltage circuit region HCR will be described.

As shown in FIG. 8, an epitaxial layer EPI that is an n-type semiconductor layer is formed on a semiconductor substrate 1S into which, for example, p-type impurities such as boron are introduced. In addition, the RESURF layer RSF that is a p-type semiconductor layer is formed on the surface of the epitaxial layer EPI. A field insulating film FI is formed on the surface of the RESURF layer RSF, and a field plate RFP is formed on the field insulating film FI. Further, a drain region DR2 that is a p-type semiconductor region is formed on the surface of the RESURF layer RSF while being apart from the field insulating film FI. On the other hand, a p-type well DPW is formed at a position apart from the RESURF layer RSF on the surface of the epitaxial layer EPI, and a source region SR2 configured using an n-type semiconductor region and a body contact region BC2 configured using a p-type semiconductor region are formed so as to be included in the p-type well DPW. In addition, a region in the p-type well DPW sandwiched between the source region SR2 and the epitaxial layer EPI serves as a channel formation region, and a gate insulating film GOX2 is formed on the channel formation region. Further, a gate electrode GE2 is formed on the gate insulating film GOX2.

The fact that the breakdown voltage can be secured even if the impurity concentration of the epitaxial layer EPI is increased in the n-channel transistor thus configured will be qualitatively described. For example, in the case where the RESURF layer RSF is not formed in FIG. 8, the positive potential of the drain region DR2 that is an n-type semiconductor region is applied when the n-channel transistor is turned off, and the ground potential is applied to the source region SR2 and the p-type well DPW having the same potential. Thus, reverse bias is applied between the p-type well DPW and the drain region DR2. As a result, the depletion layer extends in the horizontal direction of the epitaxial layer EPI sandwiched between the p-type well DPW and the drain region DR2. In this case, a distance (distance in the horizontal direction) between the p-type well DPW and the drain region DR2 in a state where the epitaxial layer EPI is completely depleted is relatively increased. This means that in the case where the breakdown voltage between the source region SR2 and the drain region DR2 is set as a boundary value condition in the Poisson equation, the potential (Ø) is qualitatively calculated by “space charge density (φ×(distance)²”. Thus, when the distance is increased, the space charge density is decreased. Namely, in the case where the RESURF layer RSF is not provided, the impurity concentration of the epitaxial layer EPI needs to be decreased in order to secure the breakdown voltage between the source region SR2 and the drain region DR2.

On the contrary, in the case where the RESURF layer RSF is provided as shown in FIG. 8, the extension of the depletion layer in the horizontal direction in the case where the RESURF layer RSF is not provided is changed to the extension of the depletion layer in the thickness direction (vertical direction) of the semiconductor substrate 1S from the p-n junction between the RESURF layer RSF and the epitaxial layer EPI. In this case, the distance is shortened relative to the boundary value condition of the breakdown voltage, and thus the space charge density is increased. Namely, even if the impurity concentration of the epitaxial layer EPI is increased, the breakdown voltage can be secured by providing the RESURF layer RSF even in the n-channel transistor. Thus, as shown in FIG. 7, in the case where the n-channel transistor and the p-channel transistor are formed in the separation region ICR of the semiconductor chip CHP, the breakdown voltage can be secured in both of the n-channel transistor and the p-channel transistor by forming the RESURF layer RSF across the entire separation region ICR.

According to the examination, however, the inventors newly found that it was difficult to decrease the on-resistance in both of the n-channel transistor and the p-channel transistor in the configuration in which the RESURF layer RSF was formed across the entire separation region ICR as shown in FIG. 7. Namely, for example, the RESURF layer RSF functions as a current path in the p-channel transistor shown in FIG. 6, and thus the on-resistance can be decreased by increasing the impurity concentration of the RESURF layer RSF. On the other hand, an increase in the impurity concentration of the RESURF layer RSF means that the width of the depletion layer extending on the epitaxial layer EPI side from the p-n junction between the RESURF layer RSF and the epitaxial layer EPI is increased. In this regard, since the epitaxial layer EPI functions as a current path in the n-channel transistor as shown in FIG. 8, an increase in the width of the depletion layer extending in the epitaxial layer EPI means that the on-resistance of the n-channel transistor is increased by considering the depletion layer functioning as an insulating region. Namely, regarding the impurity concentration of the RESURF layer RSF, a decrease in the on-resistance of the p-channel transistor and a decrease in the on-resistance of the n-channel transistor are in a trade-off relationship.

As similar to the above, for example, the epitaxial layer EPI functions as a current path in the n-channel transistor shown in FIG. 8, and thus the on-resistance can be decreased by increasing the impurity concentration of the epitaxial layer EPI. On the other hand, an increase in the impurity concentration of the epitaxial layer EPI means that the width of the depletion layer extending on the RESURF layer RSF side from the p-n junction between the RESURF layer RSF and the epitaxial layer EPI is increased. In this regard, since the RESURF layer RSF functions as a current path in the p-channel transistor as shown in FIG. 6, an increase in the width of the depletion layer extending in the RESURF layer RSF means that the on-resistance of the p-channel transistor is increased by considering the depletion layer functioning as an insulating region. Namely, regarding the impurity concentration of the epitaxial layer EPI, a decrease in the on-resistance of the n-channel transistor and a decrease in the on-resistance of the p-channel transistor are in a trade-off relationship.

As described above, in the case where the p-channel transistor and the n-channel transistor are provided in the separation region ICR of the semiconductor chip CHP as shown in FIG. 7, it is difficult to decrease the on-resistance in both of the p-channel transistor and the n-channel transistor while maintaining the breakdown voltage in the configuration in which the RESURF layer RSF is formed across the entire separation region ICR. Further, it is necessary to change the impurity concentration of the epitaxial layer EPI, and the design of the entire semiconductor chip CHP is forced to be changed.

Accordingly, the semiconductor device of the embodiment has been devised so that, for example, a decrease in the on-resistance of both of the p-channel transistor and the n-channel transistor can be simultaneously realized while maintaining the breakdown voltage without changing the impurity concentration of the epitaxial layer EPI in not only the case where the p-channel transistor is provided in the separation region ICR of the semiconductor chip CHP, but also the case where both of the p-channel transistor and the n-channel transistor are provided. Technical ideas in the devised embodiment will be described below.

### <Configuration of Semiconductor Chip in Embodiment>

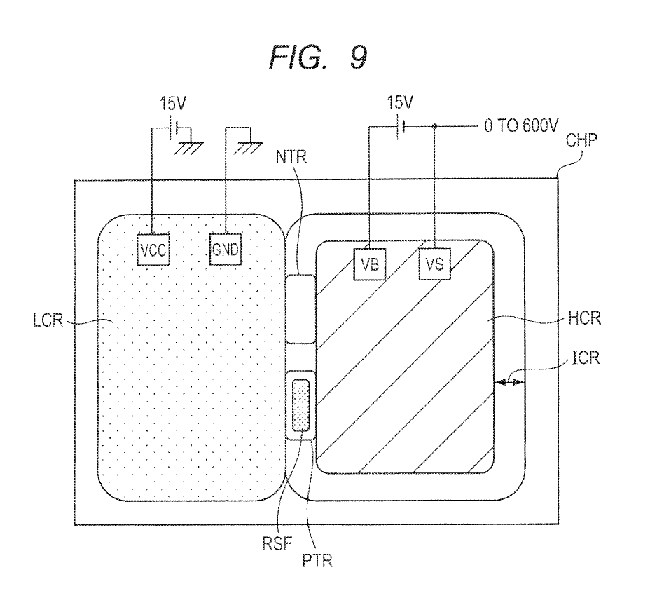

FIG. 9 is a diagram for showing a planar layout configuration of the semiconductor chip CHP in the embodiment. In FIG. 9, the semiconductor chip CHP in the embodiment has a rectangular planar shape. In addition, a low voltage circuit region LCR in which a low voltage circuit operated at a first potential with respect to a reference potential is formed, a high voltage circuit region HCR in which a high voltage circuit operated at a potential higher than the first potential with respect to the reference potential is formed, and a separation region ICR that separates the high voltage circuit region HCR from the low voltage circuit region LCR are formed in the semiconductor chip CHP.

In particular, a level down shifter having a function of signal transmission from the high voltage circuit to the low voltage circuit and a level up shifter having a function of signal transmission from the low voltage circuit to the high voltage circuit are formed in the separation region ICR of the semiconductor chip CHP in the embodiment. Specifically, a p-channel transistor formation region PTR in which a p-channel transistor functioning as the level down shifter is formed and an n-channel transistor formation region NTR in which an n-channel transistor functioning as the level up shifter is formed are formed in the separation region ICR. In this case, a RESURF layer RSF is formed in only the p-channel transistor formation region PTR in the embodiment.

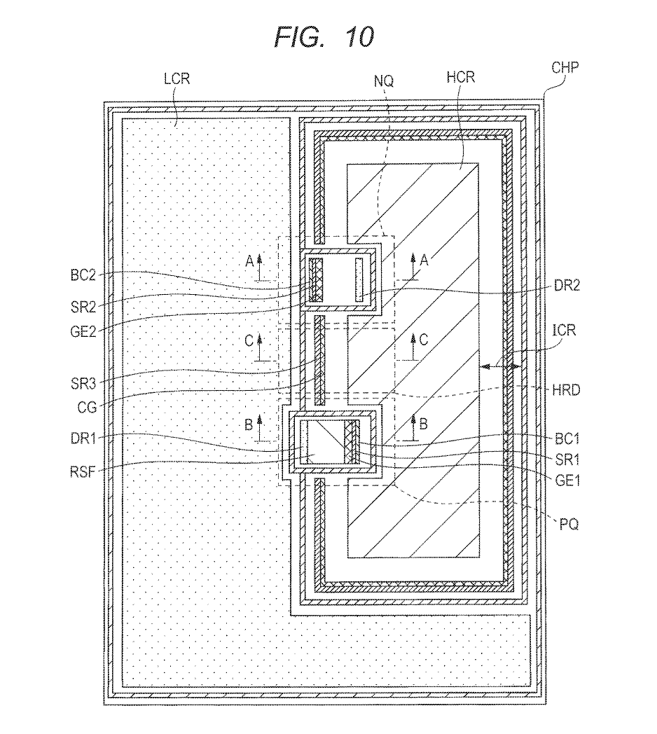

FIG. 10 is a diagram for showing a schematic planar layout configuration of an n-channel transistor NQ, a p-channel transistor PQ, and a rectifying element HRD formed in the separation region ICR in the semiconductor chip CHP.

First, the n-channel transistor NQ has a body contact region BC2, a source region SR2, a gate electrode GE2, and a drain region DR2 in FIG. 10. In addition, the body contact region BC2, the source region SR2, and the gate electrode GE2 are arranged adjacent to each other in planar view. On the other hand, the drain region DR2 and the gate electrode GE2 are arranged apart from each other in planar view.

Next, the p-channel transistor PQ has a body contact region BC1, a source region SR1, a gate electrode GE1, a RESURF layer RSF, and a drain region DR1 in FIG. 10. In addition, the body contact region BC1, the source region SR1, and the gate electrode GE1 are arranged adjacent to each other in planar view. On the other hand, the drain region DR1 and the gate electrode GE1 are arranged apart from each other in planar view. In addition, the RESURF layer RSF is formed so as to be sandwiched between the gate electrode GE1 and the drain region DR1.

Next, the rectifying element HRD has a control gate electrode CG and a source region SR3 in FIG. 10.

<Device Structure of n-Channel Transistor>

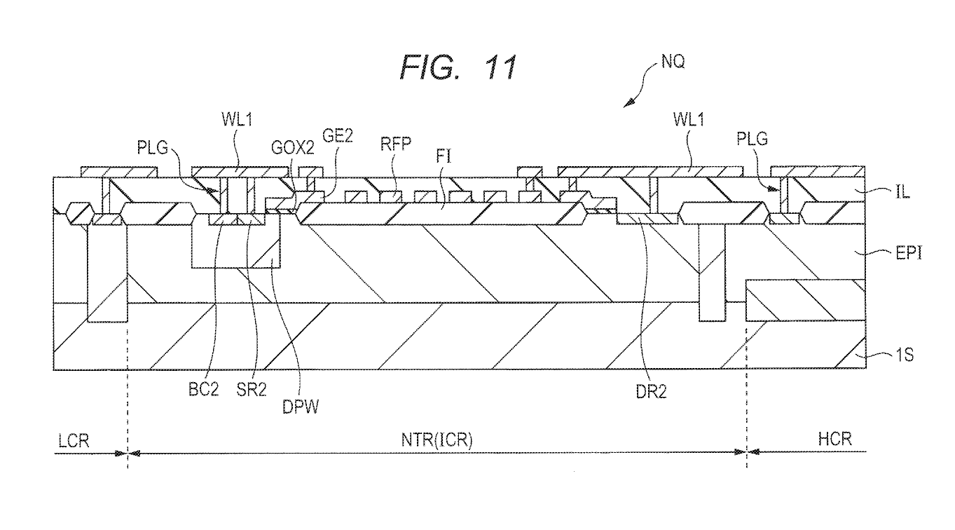

Next, a device structure of the n-channel transistor NQ functioning as the level up shifter in the embodiment will be described. FIG. 11 is a cross-sectional view taken along the line A-A of FIG. 10. In FIG. 11, a semiconductor substrate 1S and an epitaxial layer EPI that is an n-type semiconductor layer formed on the semiconductor substrate 1S are formed across the low voltage circuit region LCR, the separation region ICR (n-channel transistor formation region NTR), and the high voltage circuit region HCR. In addition, as shown in FIG. 11, the n-channel transistor NQ is formed in the n-channel transistor formation region NTR of the separation region ICR.

The n-channel transistor NQ has an electric field relaxing part formed on the surface of the epitaxial layer EPI, and the electric field relaxing part includes a field insulating film FI and a field plate RFP formed on the field insulating film FI. In addition, the n-channel transistor NQ has a p-type well DPW provided apart from the electric field relaxing part, and the source region SR2 and the body contact region (back gate region) BC2 are formed so as to be included in the p-type well DPW. The body contact region BC2 and the source region SR2 are electrically coupled to each other through a plug PLG formed in the interlayer insulating film IL and a wiring WL1 formed on the interlayer insulating film IL, and are configured so as to have the same potential. Further, the drain region DR2 is provided apart from the electric field relaxing part, and the electric field relaxing part is arranged so as to be sandwiched between the p-type well DPW and the drain region DR2. Next, a channel formation region is formed at a position sandwiched between the ends of the source region SR2 and the p-type well DPW, and a gate insulating film GOX2 is formed on the channel formation region. In addition, the gate electrode GE2 is formed on the gate insulating film GOX2.

As described above, the n-channel transistor NQ formed in the n-channel transistor formation region of the separation region ICR is turned on in such a manner that an inversion layer is formed in the channel formation region by applying a gate voltage equal to or larger than a threshold voltage to the gate electrode GE2. As a result, a current flows in the current path of the drain region DR2, the epitaxial layer EPI, the inversion layer, and the source region SR2 in this order in the n-channel transistor NQ. As described above, the level up shifter having a function of signal transmission from the low voltage circuit to the high voltage circuit is realized by the n-channel transistor NQ in which the epitaxial layer EPI is used as a current path.

<Device Structure of p-Channel Transistor>

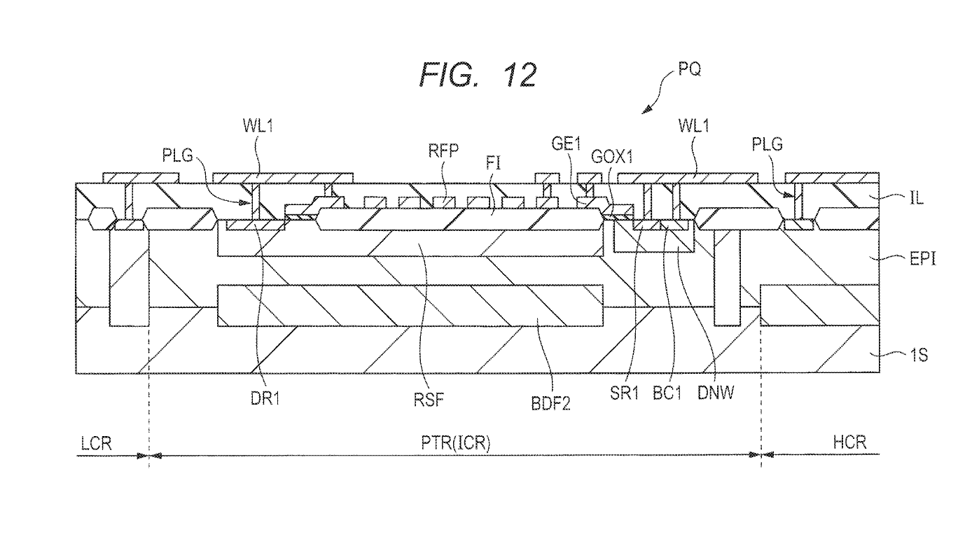

Next, a device structure of the p-channel transistor PQ functioning as the level down shifter in the embodiment will be described. FIG. 12 is a cross-sectional view taken along the line B-B of FIG. 10. In FIG. 12, a semiconductor substrate 1S and an epitaxial layer EPI that is an n-type semiconductor layer formed on the semiconductor substrate 1S are formed across the low voltage circuit region LCR, the separation region ICR (p-channel transistor formation region PTR), and the high voltage circuit region HCR. In addition, as shown in FIG. 12, the p-channel transistor PQ is formed in the p-channel transistor formation region PTR of the separation region ICR.

The p-channel transistor PQ has a RESURF layer that functions as a current path, is formed in the epitaxial layer EPI, and is a p-type semiconductor layer, and an electric field relaxing part is formed on the surface of the RESURF layer RSF. The electric field relaxing part includes a field insulating film FI, and a field plate RFP formed on the field insulating film FI. In addition, the p-channel transistor PQ has an n-type well DNW provided apart from the RESURF layer RSF, and the source region SR1 and the body contact region (back gate region) BC1 are formed so as to be included in the n-type well DNW. The body contact region BC1 and the source region SR1 are electrically coupled to each other through a plug PLG formed in the interlayer insulating film IL and a wiring WL1 formed on the interlayer insulating film IL, and are configured so as to have the same potential. Further, the drain region DR1 is provided so as to be included in the RESURF layer RSF, and the electric field relaxing part is arranged so as to be sandwiched between the n-type well DNW and the drain region DR1. Next, a channel formation region is formed at a position sandwiched between the source region SR1 and the RESURF layer RSF, and a gate insulating film GOX1 is formed on the channel formation region. In addition, the gate electrode GE1 is formed on the gate insulating film GOX1. Further, the p-channel transistor in the embodiment has a buried layer BDF2 that is overlapped with the RESURF layer RSF in planar view, is formed under the RESURF layer RSF, is sandwiched between the semiconductor substrate 1S and the epitaxial layer EPI, and is a p-type semiconductor layer. The impurity concentration of the buried layer BDF2 is higher than that of the epitaxial layer EPI.

As described above, the p-channel transistor PQ formed in the p-channel transistor formation region of the separation region ICR is turned on in such a manner that an inversion layer is formed in the channel formation region by applying a gate voltage equal to or larger than a threshold voltage to the gate electrode GE1. As a result, a current flows in the current path of the drain region DR1, the RESURF layer RSF, the inversion layer, and the source region SR1 in this order in the p-channel transistor PQ. As described above, the level down shifter having a function of signal transmission from the high voltage circuit to the low voltage circuit is realized by the p-channel transistor PQ in which the RESURF layer RSF is used as a current path.

### <Device Structure of Rectifying Element>

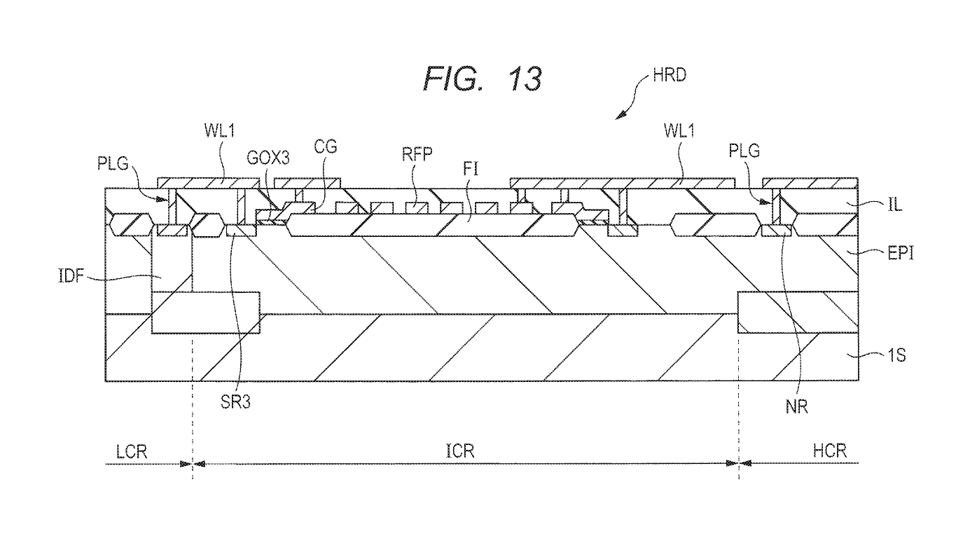

A device structure of the rectifying element HRD in the embodiment will be described. FIG. 13 is a cross-sectional view taken along the line C-C of FIG. 10. In FIG. 13, a semiconductor substrate 1S and an epitaxial layer EPI that is an n-type semiconductor layer formed on the semiconductor substrate 1S are formed across the low voltage circuit region LCR, the separation region ICR, and the high voltage circuit region HCR. In addition, as shown in FIG. 13, the rectifying element HRD is formed in the separation region ICR.

The rectifying element HRD has an electric field relaxing part formed on the surface of the epitaxial layer EPI, and the electric field relaxing part includes a field insulating film FI, and a field plate RFP formed on the field insulating film FI. In addition, the rectifying element HRD has a source region SR3 provided apart from the electric field relaxing part, and a p-type semiconductor layer IDF electrically coupled to the source region SR3 is formed so as to reach up to the semiconductor substrate 1S by penetrating the epitaxial layer EPI. On the other hand, a gate insulating film GOX3 is formed on the surface of the epitaxial layer EPI between the source region SR3 and the electric field relaxing part, and a control gate electrode CG is formed on the gate insulating film GOX3.

In the rectifying element HRD thus configured, the connection/non-connection of a depletion layer extending from the p-n junction between the p-type semiconductor layer IDF and the epitaxial layer EPI with a depletion layer extending from the epitaxial layer EPI immediately under the control gate electrode CG is controlled by a gate voltage applied to the control gate electrode CG, so that an on-operation and an off-operation of the rectifying element are switched. As a result, according to the rectifying element HRD in the embodiment, a current rectifying function can be realized.

### <Characteristics in Embodiment>

Next, characteristic points in the embodiment will be described. A first characteristic point in the embodiment is based on a case in which the p-channel transistor formation region PTR is formed in the separation region ICR that separates the high voltage circuit region HCR from the low voltage circuit region LCR as shown in, for example, FIG. 9. In addition, the first characteristic point in the embodiment is that the RESURF layer RSF that is a p-type semiconductor layer is provided in only the p-channel transistor formation region PTR of the separation region ICR without changing the impurity concentration of the epitaxial layer that is an n-type semiconductor layer formed across the low voltage circuit region LCR, the separation region ICR, and the high voltage circuit region HCR. Accordingly, it is not necessary to change the impurity concentration of the epitaxial layer formed across the low voltage circuit region LCR, the separation region ICR, and the high voltage circuit region HCR. Thus, even in the case where the RESURF layer RSF is provided in the p-channel transistor formation region PTR of the separation region ICR, the design of the devices formed in the low voltage circuit region LCR and the high voltage circuit region HCR need not be advantageously changed. This means that the p-channel transistor functioning as the level down shifter can be formed in the separation region ICR without significantly changing the design of the semiconductor chip, and thus a function can be added to the semiconductor chip without significantly changing the design of the semiconductor chip. As a result, according to the first characteristic point in the embodiment, the performance of the semiconductor device can be improved by the additional function without causing a remarkable increase in manufacturing cost.

For example, as shown in FIG. 9, even in the case where the n-channel transistor formation region NTR is provided in the separation region ICR and the n-channel transistor functioning as the level up shifter is formed in the n-channel transistor formation region NTR, it is not necessary to change the impurity concentration of the epitaxial layer already regulated from the viewpoint of satisfying both of securing of the breakdown voltage of the n-channel transistor and a decrease in the on-resistance. Accordingly, according to the first characteristic point in the embodiment, the p-channel transistor functioning as the level down shifter can be formed in the p-channel transistor formation region PTR of the separation region ICR without deteriorating the performance of the n-channel transistor.

However, if the first characteristic point in the embodiment is employed, the impurity concentration of the epitaxial layer is not changed. In this case, it is difficult to secure the breakdown voltage of the p-channel transistor having the RESURF layer RSF. Because the depletion layer extends in not the horizontal direction of the semiconductor substrate but the thickness direction (vertical direction) of the semiconductor substrate from the p-n junction between the RESURF layer RSF and the epitaxial layer by forming the RESURF layer RSF that is a p-type semiconductor layer. If the extension direction of the depletion layer is changed as described above, the impurity concentration of the epitaxial layer derived by determining the condition in which the RESURF layer RSF and the epitaxial layer are completely depleted when the designed breakdown voltage in the p-channel transistor is added to the source region and the drain region as the boundary value condition of the Poisson equation becomes higher than that of the epitaxial layer in the case where the design is not changed. Namely, the impurity concentration of the epitaxial layer in the case where the design is not changed is too low to secure the designed breakdown voltage of the p-channel transistor having the RESURF layer RSF.

Accordingly, the semiconductor device of the embodiment is devised so that the designed breakdown voltage of the p-channel transistor having the RESURF layer RSF can be secured while employing the above-described first characteristic point, and the devised point is a second characteristic point in the embodiment.

The second characteristic point in the embodiment will be described below. The second characteristic point in the embodiment is that the buried layer BDF2 that is overlapped with the RESURF layer RSF in planar view, is formed under the RESURF layer RSF, is sandwiched between the semiconductor substrate 1S and the epitaxial layer EPI, and is higher than the epitaxial layer EPI in the impurity concentration is provided in the p-channel transistor PQ as shown in, for example, FIG. 12. Accordingly, in the case where the depletion layer extends in the thickness direction (vertical direction) of the semiconductor substrate, the extension of the depletion layer in the buried layer BDF2 is suppressed because the impurity concentration of the buried layer BDF2 is high. As a result, the RESURF layer RSF and the epitaxial layer EPI are not completely depleted at a voltage lower than the designed breakdown voltage, but the RESURF layer RSF and the epitaxial layer EPI are completely depleted for the first time at the designed breakdown voltage. Thus, the designed breakdown voltage in the p-channel transistor PQ can be secured. Namely, according to the second characteristic point in the embodiment, for example, the designed breakdown voltage in the p-channel transistor PQ can be secured while employing the first characteristic point in which the impurity concentration of the epitaxial layer EPI itself is not changed by forming the buried layer BDF2 shown in FIG. 12. Namely, by providing the buried layer BDF2, it is possible to obtain the same effect as that obtained when the impurity concentration of the epitaxial layer EPI formed in the p-channel transistor formation region PTR is increased to secure the breakdown voltage of the p-channel transistor PQ.

As described above, the effect of the configuration in which the buried layer BDF2 is provided in the p-channel transistor formation region PTR is the same as that obtained when the impurity concentration of the epitaxial layer EPI formed in the p-channel transistor formation region PTR is increased in securing the designed breakdown voltage of the p-channel transistor PQ. Further, the configuration in which the buried layer BDF2 is provided in the p-channel transistor formation region PTR is superior to the configuration in which the impurity concentration of the epitaxial layer EPI formed in the p-channel transistor formation region PTR is increased in decreasing the on-resistance of the p-channel transistor PQ.

For example, if the impurity concentration of the epitaxial layer EPI is increased, the width of the depletion layer extending on the RESURF layer RSF side from the p-n junction formed at a boundary between the RESURF layer RSF and the epitaxial layer EPI is increased. This means that the resistance of the RESURF layer RSF is increased when considering the depletion layer functioning as an insulating region. In addition, an increase in the impurity concentration of the epitaxial layer EPI means an increase in the on-resistance of the p-channel transistor when considering the RESURF layer RSF functioning as a current path of the p-channel transistor. Thus, the configuration in which the impurity concentration of the epitaxial layer EPI is increased is useful from the viewpoint of securing the designed breakdown voltage of the p-channel transistor. However, in the case where a decrease in the on-resistance of the p-channel transistor is also considered, the configuration is not necessarily useful in some aspects.

On the contrary, the buried layer BDF2 that is higher than the epitaxial layer EPI in the impurity concentration is provided apart from the RESURF layer RSF without changing the impurity concentration of the epitaxial layer EPI itself in the embodiment. In this case, the designed breakdown voltage of the p-channel transistor PQ can be secured as described above. Further, the buried layer BDF2 does not come into contact with the RESURF layer RSF, and the RESURF layer RSF comes into contact with the epitaxial layer EPI having a low impurity concentration in the embodiment. In this case, the width of the depletion layer extending on the RESURF layer RSF side from the p-n junction formed at a boundary between the RESURF layer RSF and the epitaxial layer EPI becomes smaller as compared to a case in which the impurity concentration of the epitaxial layer EPI is increased. This means that the depletion layer formed on the RESURF layer RSF side becomes smaller, and thus an increase in the on-resistance of the p-channel transistor PQ can be suppressed. As described above, according to the second characteristic point in the embodiment, an increase in the on-resistance of the p-channel transistor PQ can be suppressed while securing the designed breakdown voltage of the p-channel transistor PQ unlike the configuration in which the impurity concentration of the epitaxial layer EPI itself is increased. Namely, the designed breakdown voltage of the p-channel transistor PQ can be secured in the configuration in which the impurity concentration of the epitaxial layer EPI itself is increased. On the other hand, a side effect that the on-resistance of the p-channel transistor PQ is increased becomes apparent. On the contrary, according to the second characteristic point in the embodiment in which the buried layer BDF2 is formed, an increase in the on-resistance of the p-channel transistor PQ can be suppressed while securing the designed breakdown voltage of the p-channel transistor PQ. As a result, it can be understood that the second characteristic point in the embodiment is superior to the configuration in which the impurity concentration of the epitaxial layer EPI itself is increased from the viewpoint of improving the performance of the p-channel transistor PQ.

As described above, according to the first characteristic point in the embodiment, the p-channel transistor PQ can be formed in the p-channel transistor formation region PTR of the separation region ICR without deteriorating the performance of the n-channel transistor. In addition, a side effect that a decrease in the breakdown voltage of the p-channel transistor PQ caused by the first characteristic point can be compensated by employing the second characteristic point in the embodiment without causing an increase in the on-resistance of the p-channel transistor PQ. Namely, a remarkable effect that the performance of both of the n-channel transistor and the p-channel transistor PQ formed in the separation region ICR can be improved can be obtained by the first characteristic point and the second characteristic point in the embodiment from the viewpoint of satisfying both of improvement in the breakdown voltage and suppression of an increase in the on-resistance. Namely, a combination of the first characteristic point and the second characteristic point in the embodiment has great technical significance in that the performance can be improved by satisfying both of improvement in the breakdown voltage and suppression of an increase in the on-resistance in both of the n-channel transistor and the p-channel transistor PQ.

### <Verification of Effect>

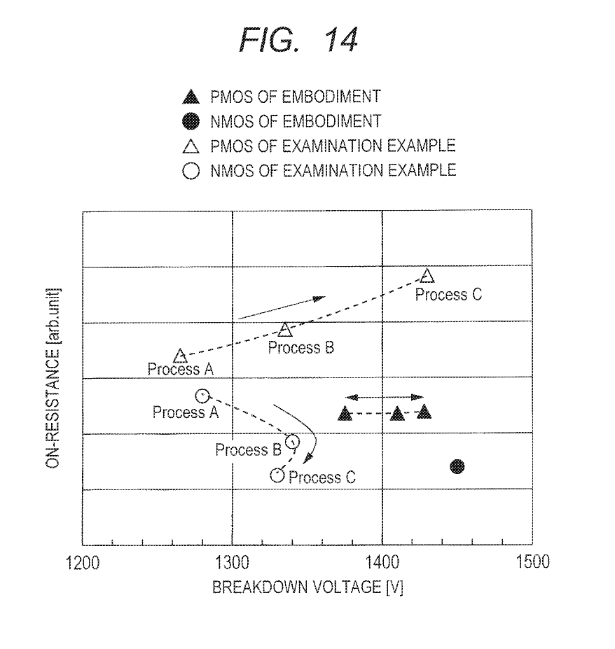

FIG. 14 is a diagram for explaining an effect in the embodiment. In FIG. 14, the vertical axis represents the on-resistance of the transistor, and the horizontal axis represents the breakdown voltage (BVds) of the transistor.

In FIG. 14, a “white triangle” represents the p-channel transistor (PMOS) of the examination example, and corresponds to, for example, the device structure of FIG. 6. A “white circle” represents the n-channel transistor (NMOS) of the examination example, and corresponds to, for example, the device structure of FIG. 8.

Further, in FIG. 14, a “black triangle” represents the p-channel transistor (PMOS) of the embodiment, and corresponds to, for example, the device structure of FIG. 12. A “black circle” represents the n-channel transistor (NMOS) of the embodiment, and corresponds to, for example, the device structure of FIG. 11.

First, the examination example will be described. The RESURF layer RSF is formed in each of the p-channel transistor (see FIG. 6) of the examination example and the n-channel transistor (see FIG. 8) of the examination example. Here, when the impurity concentration of the epitaxial layer EPI is increased while keeping the impurity concentration of the RESURF layer RSF constant, the epitaxial layer EPI functions as a current path in the n-channel transistor of the examination example, and thus the on-resistance is decreased. On the other hand, when the impurity concentration of the epitaxial layer EPI is increased, the width of the depletion layer extending on the RESURF layer RSF side is increased in the p-channel transistor of the examination example, and thus the on-resistance is increased. Namely, regarding the on-resistance, the p-channel transistor of the examination example and the n-channel transistor of the examination example in each of which the RESURF layer RSF is formed are in a trade-off relationship.

Specifically, as shown in, for example, FIG. 14, when “Process A” is employed, a combination of the p-channel transistor of the examination example and the n-channel transistor of the examination example corresponding to “Process A” is determined. In addition, when “Process B” in which the impurity concentration of the epitaxial layer EPI is increased while keeping the impurity concentration of the RESURF layer RSF constant is employed from “Process A”, a combination of the p-channel transistor of the examination example and the n-channel transistor of the examination example corresponding to “Process B” is determined. Further, when “Process C” in which the impurity concentration of the epitaxial layer EPI is increased while keeping the impurity concentration of the RESURF layer RSF constant is employed from “Process B”, a combination of the p-channel transistor of the examination example and the n-channel transistor of the examination example corresponding to “Process C” is determined.

As described above, it can be understood that a difference of the on-resistance between the p-channel transistor of the examination example and the n-channel transistor of the examination example is increased in “Process A”, “Process B”, and “Process C” in this order. Namely, the characteristics of the on-resistance of the p-channel transistor and the characteristics of the on-resistance of the n-channel transistor are associated with each other in a trade-off relationship in the examination example. Therefore, when the characteristics of one transistor are improved, the characteristics of the other transistor are deteriorated. Namely, it can be understood that it is difficult to simultaneously improve the characteristics of the p-channel transistor of the examination example and the n-channel transistor of the examination example.

On the contrary, it is not necessary to add the RESURF layer RSF to the n-channel transistor in the embodiment due to the first characteristic point in which the impurity concentration of the epitaxial layer EPI is not changed. This means that the n-channel transistor and the p-channel transistor are not associated with each other by the RESURF layer RSF in the embodiment. As a result, according to the embodiment, the characteristics of the n-channel transistor can be improved by optimizing the impurity concentration of the epitaxial layer EPI without consideration of the p-channel transistor.

On the other hand, the performance of the p-channel transistor can be improved without changing the impurity concentration of the epitaxial layer EPI by adjusting the balance of the impurity concentration between the RESURF layer RSF and the buried layer BDF2 in the embodiment due to the second characteristic point in which the RESURF layer RSF and the buried layer BDF2 are formed in only the p-channel transistor.

As described above, the performance of the n-channel transistor can be improved by the impurity concentration of the epitaxial layer EPI in the embodiment. On the other hand, the performance of the p-channel transistor can be improved by adjusting the balance of the impurity concentration between the RESURF layer RSF and the buried layer BDF2. Namely, the performance of each transistor can be improved not by the adjustment in the constitutional elements that are associated with each other in a trade-off relationship but by the adjustment in the constitutional elements that are independent from each other. As described above, the characteristics of the p-channel transistor in the embodiment and the n-channel transistor in the embodiment can be simultaneously improved. As shown in, for example, FIG. 14, the performance of the p-channel transistor can be improved (black triangle) by adjusting the balance of the impurity concentration between the RESURF layer RSF and the buried layer BDF2 while improving the performance of the n-channel transistor (black circle) by optimizing the impurity concentration of the epitaxial layer EPI.

### Modified Example 1

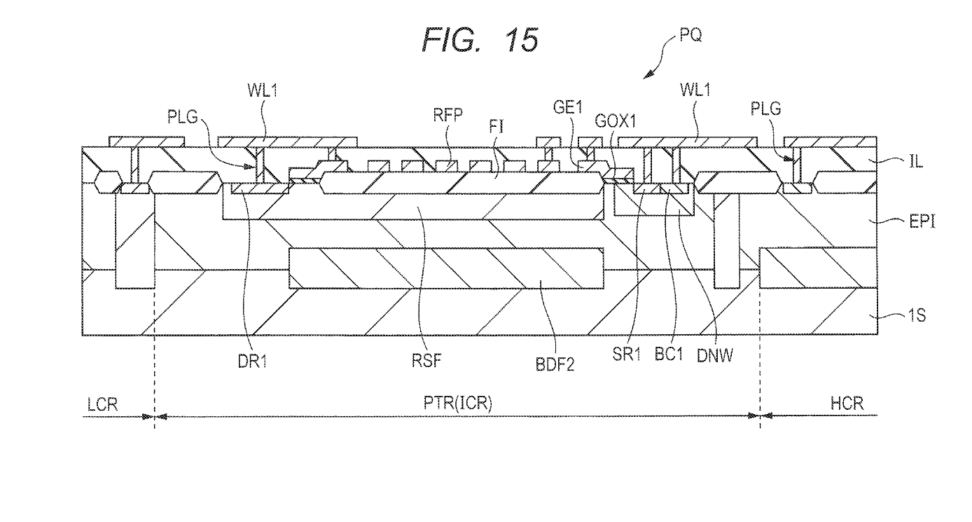

Next, a modified example 1 of the embodiment will be described. FIG. 15 is a cross-sectional view for showing a device structure of a p-channel transistor PQ in the modified example 1. As shown in FIG. 15, in the p-channel transistor PQ in the modified example 1, the RESURF layer RSF is formed so as to include the buried layer BDF2 in planar view. As similar to the buried layer BDF2 in the embodiment, an increase in the on-resistance can be suppressed by the buried layer BDF2 thus configured while securing the breakdown voltage of the p-channel transistor PQ. Namely, the performance of the p-channel transistor PQ can be improved by forming the buried layer BDF2 in the modified example 1 while adjusting the balance of the impurity concentration between the RESURF layer RSF and the buried layer BDF2 without changing the impurity concentration of the epitaxial layer EPI.

### Modified Example 2

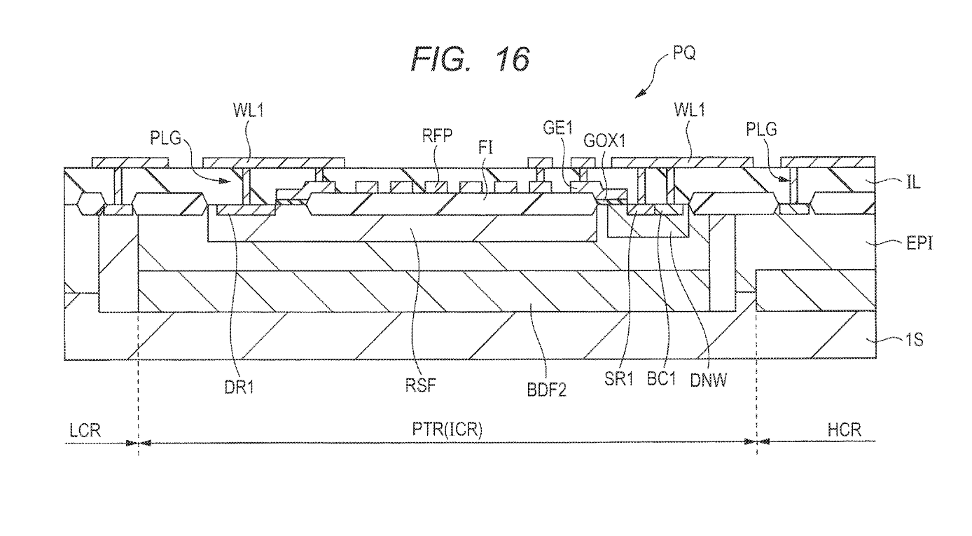

Next, a modified example 2 of the embodiment will be described. FIG. 16 is a cross-sectional view for showing a device structure of a p-channel transistor PQ in the modified example 2. As shown in FIG. 16, in the p-channel transistor PQ in the modified example 2, the RESURF layer RSF is formed so as to include the buried layer BDF2 in planar view. As similar to the buried layer BDF2 in the embodiment, an increase in the on-resistance can be suppressed by the buried layer BDF2 thus configured while securing the breakdown voltage of the p-channel transistor PQ. Namely, the performance of the p-channel transistor PQ can be improved by forming the buried layer BDF2 in the modified example 2 while adjusting the balance of the impurity concentration between the RESURF layer RSF and the buried layer BDF2 without changing the impurity concentration of the epitaxial layer EPI.

### <Manufacturing Method of Semiconductor Device in Embodiment>

The semiconductor device in the embodiment is configured as described above, and a manufacturing method thereof will be described below with reference to the drawings.

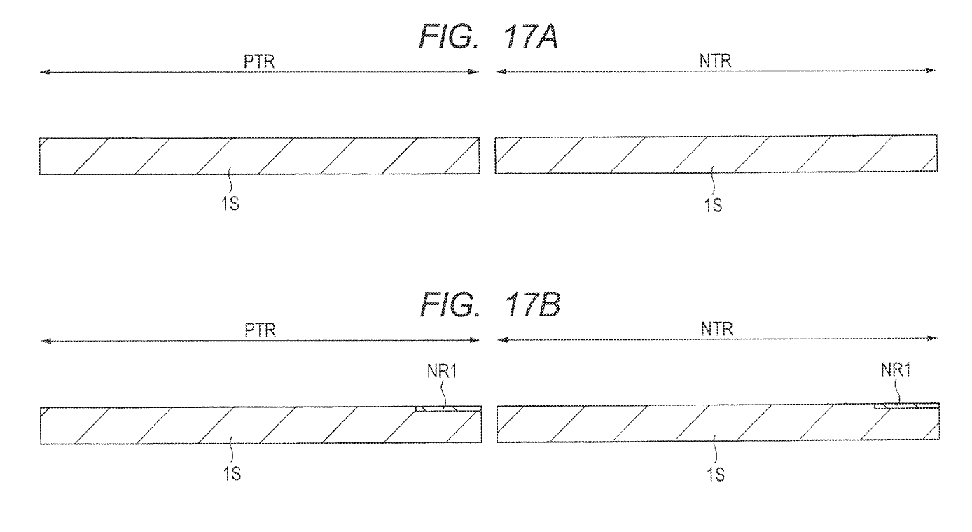

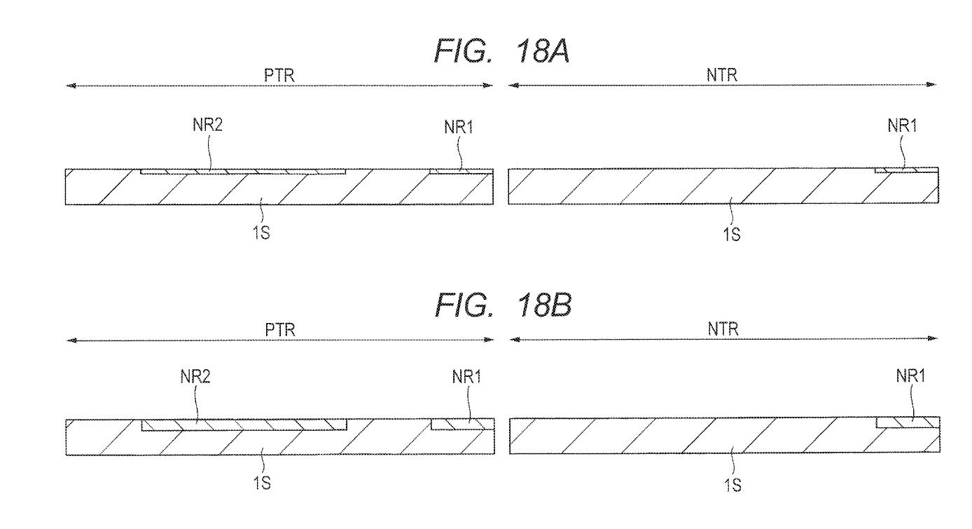

First, as shown in FIG. 17A, the semiconductor substrate 1S having the p-channel transistor formation region PTR and the n-channel transistor formation region NTR is prepared. Next, as shown in FIG. 17B, an n-type semiconductor region NR1 is formed by introducing n-type impurities (phosphorus and arsenic) into a part of the p-channel transistor formation region PTR and a part of the n-channel transistor formation region NTR by using a photolithography technique and an ion implantation method. Thereafter, as shown in FIG. 18A, an n-type semiconductor region NR2 is formed in the p-channel transistor formation region PTR while being apart from the n-type semiconductor region NR1 by using a photolithography technique and an ion implantation method. In addition, as shown in FIG. 18B, a thermal process is conducted at about 1200° C. in a mixed gas atmosphere of nitrogen and oxygen. Accordingly, the n-type impurities introduced in each of the n-type semiconductor region NR1 and the n-type semiconductor region NR2 diffuse. As a result, the thicknesses of the n-type semiconductor region NR1 and the n-type semiconductor region NR2 are increased.

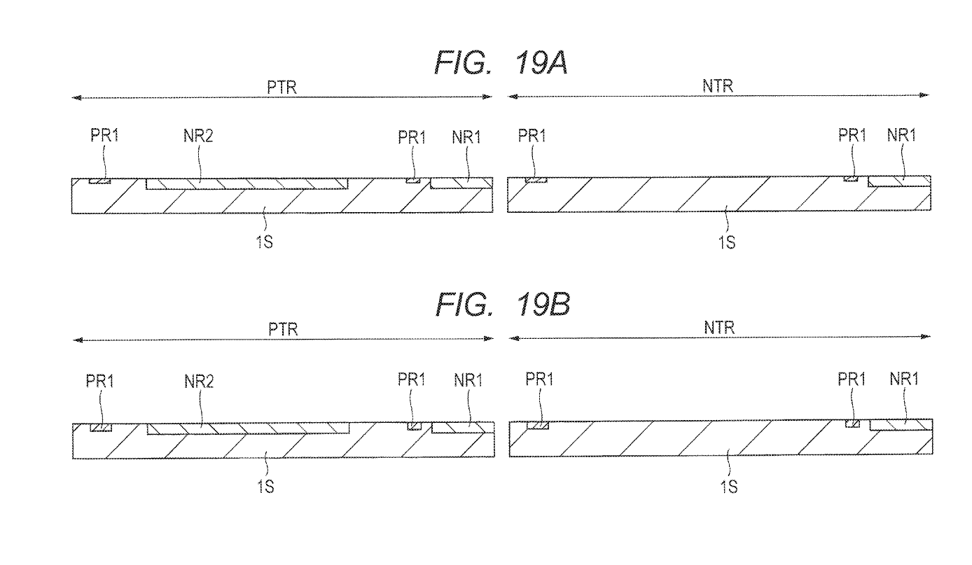

Next, as shown in FIG. 19A, a p-type semiconductor region PR1 is formed by introducing p-type impurities (boron) into a part of the p-channel transistor formation region PTR and a part of the n-channel transistor formation region NTR by using a photolithography technique and an ion implantation method. Thereafter, as shown in FIG. 19B, a thermal process is conducted at about 900° C. in a mixed gas atmosphere of nitrogen and oxygen. Accordingly, the p-type impurities introduced in the p-type semiconductor region PR1 diffuse. As a result, the thickness of the p-type semiconductor region PR1 is increased. In this case, the n-type impurities introduced in each of the n-type semiconductor region NR1 and the n-type semiconductor region NR2 further diffuse. As a result, the thicknesses of the n-type semiconductor region NR1 and the n-type semiconductor region NR2 are further increased.

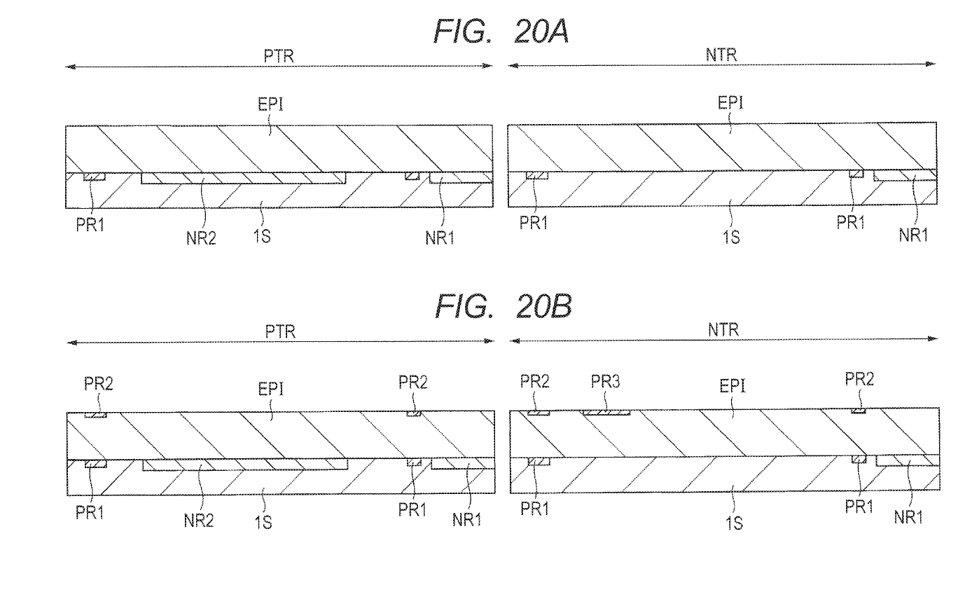

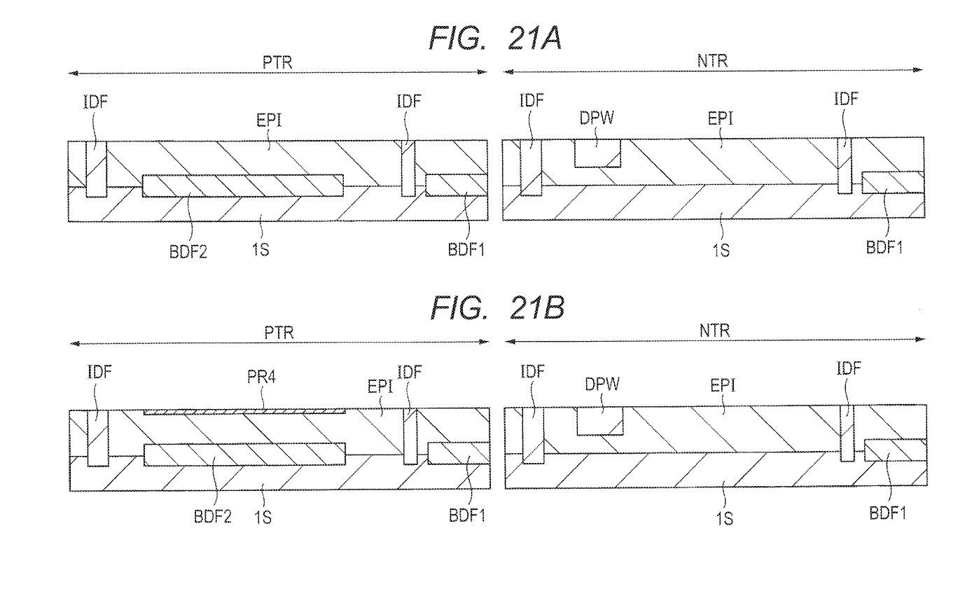

Next, as shown in FIG. 20A, the epitaxial layer EPI that is an n-type semiconductor layer is formed on the semiconductor substrate 1S by using an epitaxial growth method. In addition, as shown in FIG. 20B, a p-type semiconductor region PR2 is formed on the surface of the epitaxial layer EPI formed in the p-channel transistor formation region PTR by using a photolithography technique and an ion implantation method. As similar to the above, the p-type semiconductor region PR2 and a p-type semiconductor region PR3 that are apart from each other are formed on the surface of the epitaxial layer EPI formed in the n-channel transistor formation region NTR. Thereafter, as shown in FIG. 21A, a thermal process is conducted at about 1200° C. in a mixed gas atmosphere of nitrogen and oxygen. Accordingly, for example, the p-type semiconductor region PR1 formed in the semiconductor substrate 1S and the p-type semiconductor region PR2 formed in the epitaxial layer EPI are coupled to each other by thermal diffusion of the p-type impurities in the p-channel transistor formation region PTR. As a result, the p-type semiconductor layer IDF is formed. As similar to the above, the p-type semiconductor region PR1 formed in the semiconductor substrate 1S and the p-type semiconductor region PR2 formed in the epitaxial layer EPI are coupled to each other by thermal diffusion of the p-type impurities in the n-channel transistor formation region NTR. As a result, the p-type semiconductor layer IDF is formed. Further, the p-type semiconductor region PR3 formed on the surface of the epitaxial layer EPI spreads in the n-channel transistor formation region NTR, and the p-type well DPW is formed.

Further, the n-type semiconductor region NR1 formed in the semiconductor substrate 1S is diffused up to the epitaxial layer EPI formed on the semiconductor substrate 1S by the thermal process in FIG. 21A. As a result, as shown in FIG. 21A, a buried layer BDF1 sandwiched between the semiconductor substrate 1S and the epitaxial layer EPI is formed in each of the p-channel transistor formation region PTR and the n-channel transistor formation region NTR. Further, the n-type semiconductor region NR2 formed in the semiconductor substrate 1S is also diffused up to the epitaxial layer EPI formed on the semiconductor substrate 1S in the p-channel transistor formation region PTR. As a result, as shown in FIG. 21A, the buried layer BDF2 sandwiched between the semiconductor substrate 1S and the epitaxial layer EPI is also formed in the p-channel transistor formation region PTR. The impurity concentration of the buried layer BDF2 is higher than that of the epitaxial layer EPI. It should be noted that the buried layer BDF2 sandwiched between the semiconductor substrate 1S and the epitaxial layer EPI is not formed in the n-channel transistor formation region NTR.

Next, as shown in FIG. 21B, a p-type semiconductor region PR4 is formed at a position overlapped with the buried layer BDF2 in planar view on the surface of the epitaxial layer EPI in the p-channel transistor formation region PTR by using a photolithography technique and an ion implantation method.

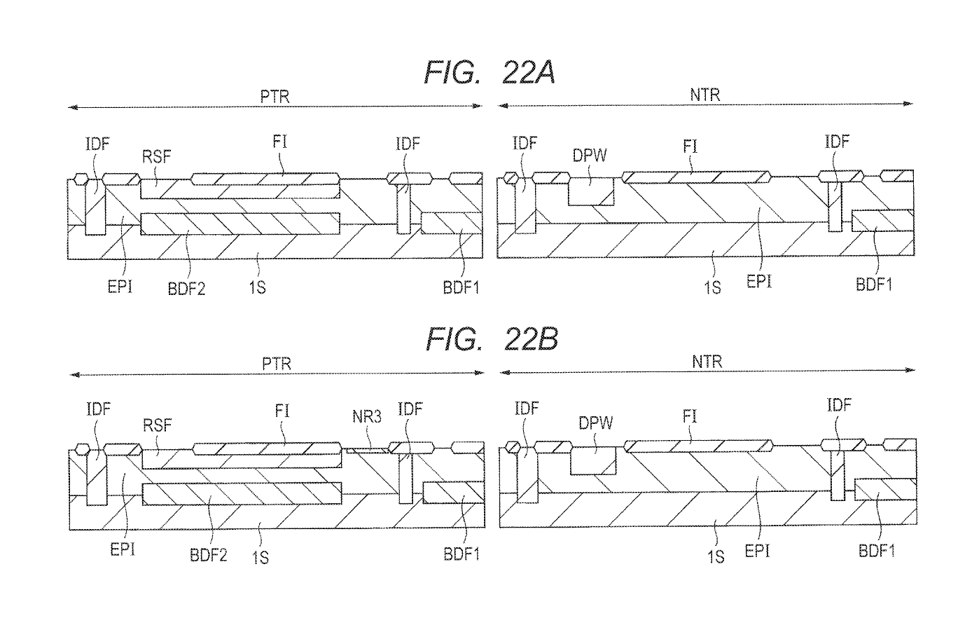

Next, as shown in FIG. 22A, the field insulating film FI is formed by conducting a thermal process at about 1050° C. in a mixed gas atmosphere of nitrogen and oxygen by using a LOCOS (Local oxidation of silicon) method. The p-type semiconductor region PR4 formed on the surface of the epitaxial layer EPI spreads due to thermal diffusion by the thermal process at this time. As a result, the RESURF layer RSF is formed at a position that is upwardly apart from the buried layer BDF2 and is overlapped with the buried layer BDF2 in planar view in the p-channel transistor formation region PTR. On the other hand, the RESURF layer RSF is not formed in the n-channel transistor formation region NTR.

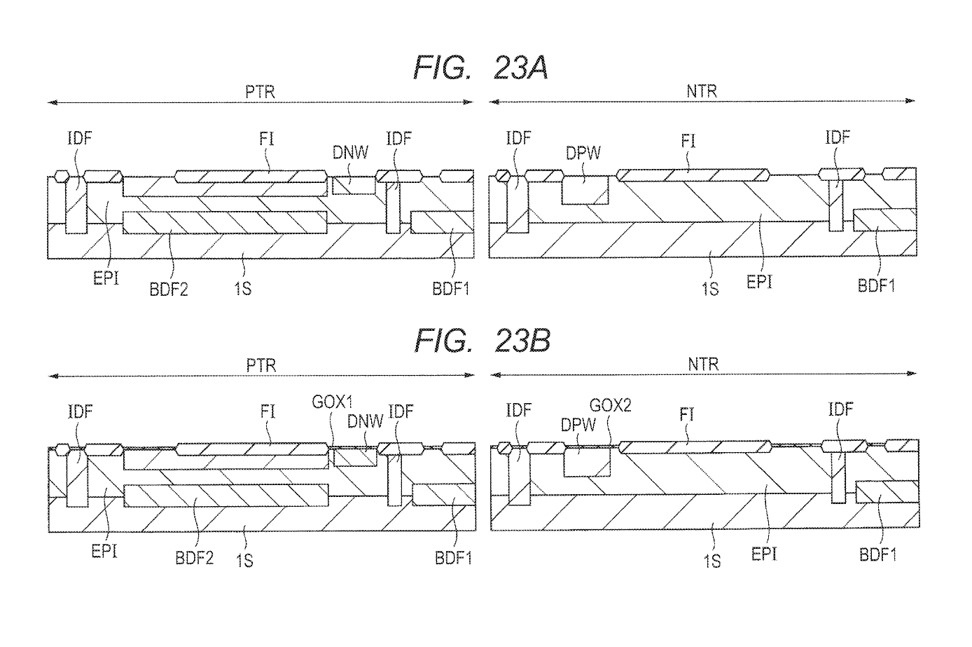

Thereafter, as shown in FIG. 22B, an n-type semiconductor region NR3 is formed at a part of the surface of the epitaxial layer EPI in the p-channel transistor formation region PTR by using a photolithography technique and an ion implantation method. In addition, a thermal process is conducted at about 1200° C. in a mixed gas atmosphere of nitrogen and oxygen. As a result, as shown in FIG. 23A, the n-type semiconductor region NR3 spreads due to thermal diffusion, so that the n-type well DNW is formed in the p-channel transistor formation region PTR.

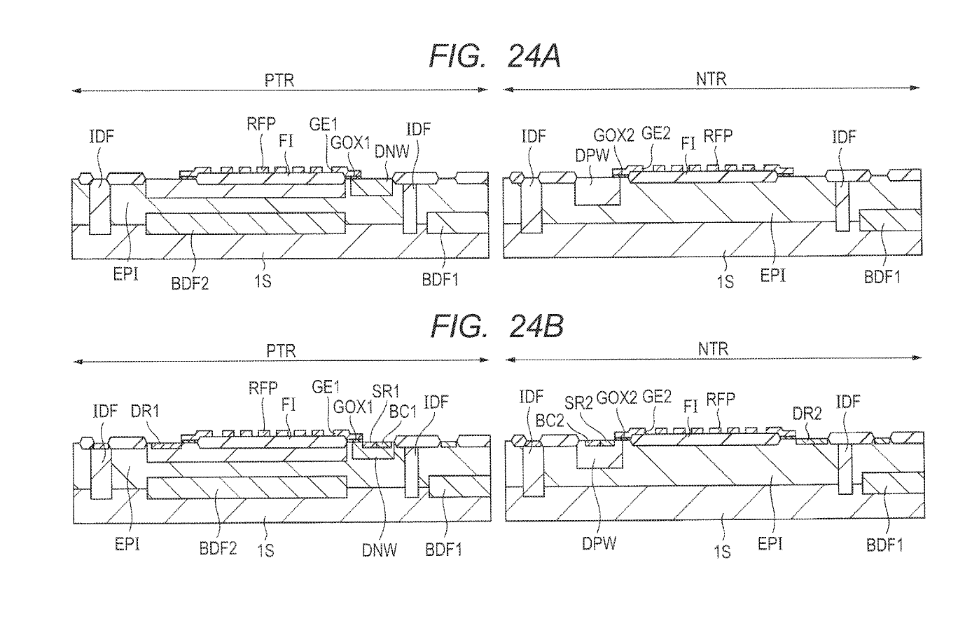

Next, as shown in FIG. 23B, the gate insulating film GOX1 is formed on the surface of the epitaxial layer EPI exposed in the p-channel transistor formation region PTR and the gate insulating film GOX2 is formed on the surface of the epitaxial layer EPI exposed in the n-channel transistor formation region NTR by conducting, for example, vapor oxidation at 800° C. In addition, as shown in FIG. 24A, for example, a polysilicon film is formed on the epitaxial layer EPI with the field insulating film FI formed. Thereafter, the polysilicon film is patterned by using a photolithography technique and an etching technique. Accordingly, for example, the gate electrode GE1 and the field plate RFP are formed in the p-channel transistor formation region PTR, and the gate electrode GE2 and the field plate RFP are formed in the n-channel transistor formation region NTR.

Next, as shown in FIG. 24B, the drain region DR1, the source region SR1, and the body contact region BC1 are formed in the p-channel transistor formation region PTR and the drain region DR2, the source region SR2, and the body contact region BC2 are formed in the n-channel transistor formation region NTR by using a photolithography technique and an ion implantation method.

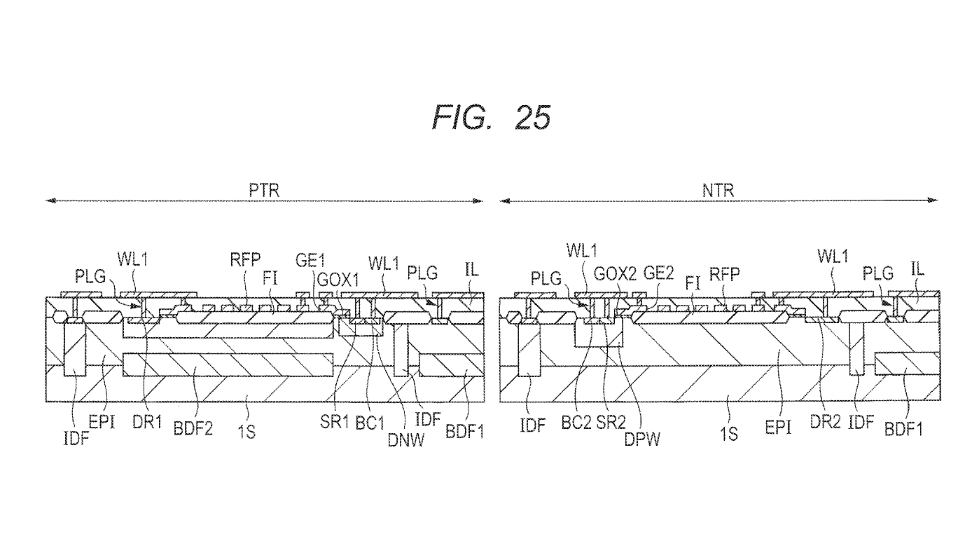

Thereafter, as shown in FIG. 25, the interlayer insulating film IL that is configured using, for example, a silicon oxide film is formed across the p-channel transistor formation region PTR and the n-channel transistor formation region NTR. In addition, a contact hole is formed in the interlayer insulating film IL and the plug PLG is formed by burying a conductive film into the contact hole by using a photolithography technique and an etching technique. Further, a metal film configured using, for example, an aluminum film is formed on the interlayer insulating film IL with the plug PLG formed, and then the wiring WL1 is formed by patterning the metal film by using a photolithography technique and an etching technique. The semiconductor device can be manufactured as described above.

### Modified Example

In the embodiment, the n-type semiconductor region NR1 is formed as shown in, for example, FIG. 17B, and then the n-type semiconductor region NR2 is formed by an ion implantation method using another mask as shown in FIG. 18A. This is because the impurity concentration of the buried layer BDF1 formed on the basis of the n-type semiconductor region NR1 remarkably differs from that of the buried layer BDF2 formed on the basis of the n-type semiconductor region NR2. Namely, the buried layer BDF1 is, for example, a layer formed in the high voltage circuit region, and is a layer formed to prevent punch-through and fluctuation of the ground potential. On the other hand, the buried layer BDF2 is a layer formed in the separation region, and is a layer formed to satisfy both of securing of the breakdown voltage of the p-channel transistor formed in the separation region and a decrease in the on-resistance. Thus, the buried layer BDF1 and the buried layer BDF2 are completely different from each other in functions to be achieved, and thus the impurity concentration of the buried layer BDF1 remarkably differs from that of the buried layer BDF2. Therefore, it is difficult to form the n-type semiconductor region NR1 and the n-type semiconductor region NR2 by the same ion implantation process, and thus the n-type semiconductor region NR1 and the n-type semiconductor region NR2 are necessarily formed in different processes.

However, in the case where the buried layer BDF2 is formed in a dot shape, the functions to be achieved can be realized. On the other hand, the n-type semiconductor region NR1 and the n-type semiconductor region NR2 can be formed by the same ion implantation process. Because substantially the same effect as the embodiment can be obtained by arranging the buried layer BDF2 in a dot shape so that the impurity concentration per unit area between the source region and the drain region of the p-channel transistor formed in the separation region is 1×10¹²/cm² to 3×10¹²/cm² when the impurity concentration of the buried layer BDF is, for example, 1×10¹³/cm².

In addition, in the case of the configuration, a dotted pattern is formed in a mask used when the n-type semiconductor region NR1 is formed by an ion implantation method, so that the impurity concentration per unit area using the dotted buried layer BDF2 can be realized by an ion implantation process using the same mask. Thus, according to the modified example, a decrease in manufacturing cost caused by a decrease in the number of masks and processes can be realized while obtaining the substantially same effect as the embodiment.

The invention achieved by the inventors has been described above in detail on the basis of the embodiment. However, it is obvious that the present invention is not limited to the above-described embodiment, but can be variously changed without departing from the scope thereof.

What is claimed is:

1. A semiconductor device comprising a semiconductor chip having:
a first circuit region in which a low voltage circuit operated at a first potential with respect to a reference potential is formed;
a second circuit region in which a high voltage circuit operated at a potential higher than the first potential with respect to the reference potential is formed; and
a separation region that separates the second circuit region from the first circuit region,
wherein a first transistor for level shift having a function of signal transmission from the high voltage circuit to the low voltage circuit is formed in the separation region,
wherein a semiconductor substrate and an epitaxial layer that is formed on the semiconductor substrate and is of a first conductive type are formed in the first circuit region, the second circuit region, and the separation region, and
wherein the first transistor for level shift formed in the separation region has a RESURF layer that functions as a current path, is formed in the epitaxial layer, and is of a second conductive type opposite to the first conductive type, and a buried layer that is overlapped with the RESURF layer in planar view, is formed under the RESURF layer, is sandwiched between the semiconductor substrate and the epitaxial layer, and is of the first conductive type.

2. The semiconductor device according to claim 1,
wherein the RESURF layer includes the buried layer in planar view.

3. The semiconductor device according to claim 1,
wherein the RESURF layer is included in the buried layer in planar view.

4. The semiconductor device according to claim 1,
wherein the impurity concentration of the buried layer is higher than that of the epitaxial layer.

5. The semiconductor device according to claim 1,
wherein the first transistor for level shift has:
an electric field relaxing part formed on the surface of the RESURF layer;
a first source region provided apart from the RESURF layer;
a first drain region provided so as to be included in the RESURF layer;
a first channel formation region sandwiched between the RESURF layer and the first source region;
a first gate insulating film formed on the first channel formation region; and
a first gate electrode formed on the first gate insulating film, and
wherein the RESURF layer is provided between the first source region and the first drain region.

6. The semiconductor device according to claim 5,
wherein the electric field relaxing part includes a field insulating film formed at a part of the surface of the RESURF layer and a field plate formed on the field insulating film.

7. The semiconductor device according to claim 1,
wherein a second transistor for level shift that has a function of signal transmission from the low voltage circuit to the high voltage circuit and uses the epitaxial layer as a current path is formed in the separation region, and
wherein the RESURF layer and the buried layer are layers formed in only the first transistor for level shift.

8. The semiconductor device according to claim 7,
wherein the second transistor for level shift has:
an electric field relaxing part formed on the surface of the epitaxial layer;
a second source region provided apart from the electric field relaxing part;
a second drain region provided apart from the electric field relaxing part;
a second channel formation region sandwiched between the electric field relaxing part and the second source region;
a second gate insulating film formed on the second channel formation region; and
a second gate electrode formed on the second gate insulating film.

9. The semiconductor device according to claim 1,
wherein a rectifying element having a third gate electrode is formed in the separation region, and
wherein the rectifying element switches an on-operation and an off-operation of the rectifying element by controlling the extension of a depletion layer formed in the epitaxial layer on the basis of a gate voltage applied to the third gate electrode.

10. The semiconductor device according to claim 1,
wherein the semiconductor device is a constitutional element of an inverter.

11. The semiconductor device according to claim 10,
wherein the inverter includes a high-side power transistor and a low-side power transistor,
wherein the high voltage circuit is configured to be able to control the high-side power transistor, and
wherein the low voltage circuit is configured to be able to control the low-side power transistor.

12. A manufacturing method of a semiconductor device including a p-channel transistor comprising the steps of:
(a) introducing p-type impurities into a p-channel transistor formation region of a semiconductor substrate;
(b) after the step (a), forming an n-type epitaxial layer in the p-channel transistor formation region of the semiconductor substrate;
(c) after the step (b), diffusing the p-type impurities by heating the semiconductor substrate to form an n-type buried layer sandwiched between the semiconductor substrate and the n-type epitaxial layer; and
(d) after the step (c), forming a p-type RESURF layer at a position overlapped with the n-type buried layer in planar view on the surface of the n-type epitaxial layer.

13. The manufacturing method of a semiconductor device according to claim 12,
wherein the impurity concentration of the n-type buried layer is higher than that of the n-type epitaxial layer.

14. The manufacturing method of a semiconductor device according to claim 12,
wherein the semiconductor substrate further has an n-channel transistor formation region,
wherein the n-type epitaxial layer is also formed in the n-channel transistor formation region of the semiconductor substrate in the step (b),
wherein the n-type buried layer is not formed in the n-channel transistor formation region in the step (c), and
wherein the p-type RESURF layer is not formed in the n-channel transistor formation region in the step (d).

15. The manufacturing method of a semiconductor device according to claim 14,
wherein the semiconductor substrate has:
a first circuit region in which a low voltage circuit operated at a first potential with respect to a reference potential is formed;
a second circuit region in which a high voltage circuit operated at a potential higher than the first potential with respect to the reference potential is formed; and
a separation region that separates the second circuit region from the first circuit region, and
wherein the p-channel transistor formation region and the n-channel transistor formation region exist in the separation region.
